(19) United States
(12) Patent Application Publication
(10) Pub. No.: US 2023/0052149 A1
(43) Pub. Date: Feb. 16, 2023

(54) Equipment For Manufacturing Light-Emitting Device and Light-Receiving Device

(71) Applicant: Semiconductor Energy Laboratory Co., Ltd., Kanagawa-ken (JP)

(72) Inventors: Shunpei Yamazaki, Tokyo (JP); Yasuhiro Jinbo, lsehara (JP); Tomoya Aoyama, Atsugi (JP); Daiki Nakamura, Atsugi (JP)

(73) Assignee: Semiconductor Energy Laboratory Co., Ltd., Kanagawa-ken (JP)

(21) Appl. No.: 17/872,498

(22) Filed: Jul. 25, 2022

(30) Foreign Application Priority Data
Jul. 29, 2021 (JP) 2021-124384
Aug. 5, 2021 (JP) 2021-129145

(51) Int. Cl. H01L 51/56

(52) U.S. Cl. CPC H01L 51/56; H01L 51/5253

(57) ABSTRACT

Manufacturing equipment with which steps from processing to sealing of an organic compound film can be continuously performed is provided. The manufacturing equipment enables continuous processing of a patterning step of a light-emitting device and a light-receiving device and a step of sealing top and side surfaces of organic layers to prevent the top and side surfaces from being exposed to the air, which allows formation of the light-emitting device and the light-receiving device each of which has a minute structure, high luminous, and high reliability. This manufacturing equipment can be built in an in-line manufacturing system where apparatuses are arranged according to the order of process steps for the light-emitting device and the light-receiving device, resulting in high throughput manufacturing.

### BACKGROUND OF THE INVENTION

### 1. Field of the Invention

One embodiment of the present invention relates to equipment for manufacturing a light-emitting device and a light-receiving device and a manufacturing method thereof.

Note that one embodiment of the present invention is not limited to the above technical field. The technical field of one embodiment of the present invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting device, a lighting device, a power storage device, a memory device, an imaging device, a method for operating any of them, and a method for manufacturing any of them.

### 2. Description of the Related Art

In recent years, higher resolution has been required for display panels. Examples of devices that require high-resolution display panels include a smartphone, a tablet terminal, and a laptop computer. Furthermore, higher definition has been required for a stationary display device such as a television device or a monitor device along with an increase in resolution. A device absolutely required to have a high-definition display panel is a device for virtual reality (VR) or augmented reality (AR).

Examples of the display device that can be used for a display panel include, typically, a liquid crystal display device, a light-emitting apparatus including a light-emitting device such as an organic electroluminescence (EL) element or a light-emitting diode (LED), and electronic paper performing display by an electrophoretic method or the like.

For example, an organic EL element that is a light-emitting element has a structure where a layer containing a light-emitting organic compound is sandwiched between a pair of electrodes. By voltage application to this element, the light-emitting organic compound can emit light. A display device including such an organic EL element does not need a backlight that is necessary for a liquid crystal display device and the like, and thus can have advantages such as thinness, lightweight, high contrast, and low power consumption. Patent Document 1, for example, discloses an example of a display device using an organic EL element.

### REFERENCE

[Patent Document 1] Japanese Published Patent Application No. 2002-324673

### SUMMARY OF THE INVENTION

As an organic EL display device capable of full-color display, a structure in which a white light-emitting device and color filters are combined and a structure in which red, green, and blue light-emitting devices are formed in the same plane are known.

The latter structure is optimal in terms of power consumption, and light-emitting materials are separately deposited using a metal mask or the like (side-by-side process) in manufacture of medium- and small-size panels under the existing circumstances. However, the process using a metal mask causes a problem such as low alignment accuracy and needs a reduction in an area occupied by light-emitting devices in a pixel, resulting in difficulty in increasing an aperture ratio.

Therefore, an object of the process using a metal mask is to increase density of pixels and emission intensity. It is preferable to extend an area of a light-emitting device with use of a lithography step or the like for increasing the aperture ratio. However, the reliability of the light-emitting device is lowered when impurities (such as water, oxygen, or hydrogen) in the air enters an organic compound included in the light-emitting device. Hence, a plurality of process steps for the light-emitting device have to be performed in a region whose atmosphere is controlled.

In the case where a light-emitting device is fabricated with a vacuum evaporation method using a metal mask, an issue such as necessity of a plurality of manufacturing equipment lines arises. For example, since a metal mask has to be cleaned regularly, at least two or more manufacturing equipment lines are necessary, and one of the lines is used for device fabrication while the other equipment line is being under maintenance. In consideration of mass production, a plurality of manufacturing equipment lines are required. Thus, the issue is that the initial investment for introducing manufacturing equipment significantly increases.

Furthermore, there is a demand for small-size high-resolution displays for AR and VR. Displays for AR and VR are incorporated into devices with small volume, such as glasses-type or goggle-type devices, and accordingly preferably have narrow bezels. Therefore, drivers for a pixel circuit and the like of the displays are preferably provided below the pixel circuit.

When the pixel density is increased, a pixel including a light-receiving device can be provided in a pixel portion. The pixel including a light-receiving device can function as a camera for measuring a sight line, which enables devices for AR and VR to have high functionality and small sizes.

In view of the above, one of objects of one embodiment of the present invention is to provide equipment for manufacturing a light-emitting device and a light-receiving device, with which steps from processing to sealing of an organic compound film in the devices can be continuously performed. Another object is to provide equipment for manufacturing a light-emitting device and a light-receiving device, with which steps from formation to sealing of the devices can be continuously performed. Another object is to provide equipment for manufacturing a light-emitting device and a light-receiving device which enables formation of the devices without a metal mask. Another object is to provide a method for manufacturing a light-emitting device and a light-receiving device.

Note that the description of these objects does not preclude the existence of other objects. One embodiment of the present invention does not necessarily achieve all the objects listed above. Other objects will be apparent from and can be derived from the description of the specification, the drawings, the claims, and the like.

One embodiment of the present invention relates to equipment for manufacturing a light-emitting device and a light-receiving device.

One embodiment of the present invention is an equipment for manufacturing a light-emitting device and a light-receiving device, including a first cluster, a second cluster, a third cluster, a fourth cluster, a fifth cluster, a sixth cluster, and a seventh cluster. The second cluster is connected to the first cluster through a first buffer chamber; the third cluster is connected to the second cluster through a second buffer chamber; the fourth cluster is connected to the third cluster through a third buffer chamber; the fifth cluster is connected to the fourth cluster through a fourth buffer chamber; the sixth cluster is connected to the fifth cluster through a fifth buffer chamber; and the seventh cluster is connected to the sixth cluster through a sixth buffer chamber. The first cluster is configured to form a first stacked film in which a first organic compound film, a first inorganic film, and a second inorganic film are stacked in this order. The second cluster is configured to form a first resist mask over the first stacked film. The third cluster is configured to form a light-emitting layer of the light-emitting device by etching the first stacked film and to remove the first resist mask. The fourth cluster is configured to form a second stacked film in which a second organic compound film, a third inorganic film, and a fourth inorganic film are stacked in this order. The fifth cluster is configured to form a second resist mask over the second stacked film. The sixth cluster is configured to form a photoelectric conversion layer of the light-receiving device by etching the second stacked film, to remove the second resist mask, to remove the second inorganic film and the fourth inorganic film, and to form a fifth inorganic film covering a side surface of the light-emitting layer and a side surface of the photoelectric conversion layer. The seventh cluster is configured to coat the fifth inorganic film with a resin in an inert gas atmosphere, to remove part of the resin, and to cure the resin.

The sixth cluster can include a first dry etching apparatus, a second dry etching apparatus, a third dry etching apparatus, and a film-formation apparatus. The second cluster can include a coating apparatus, a first baking apparatus, a light-exposure apparatus, a development apparatus, and a second baking apparatus.

The second dry etching apparatus can have an ashing function.

The film-formation apparatus can be an ALD apparatus.

The equipment for manufacturing a light-emitting device and a light-receiving device can further include an eighth cluster, and the eighth cluster is connected to the seventh cluster through a seventh buffer chamber. The eighth cluster can be configured to etch the fifth inorganic film and the first inorganic film with use of the resin as a mask.

The eighth cluster can include a fourth dry etching apparatus and a first wet etching apparatus. Alternatively, the eighth cluster can include the first wet etching apparatus and a second wet etching apparatus.

The eighth cluster can be configured to etch the fifth inorganic film with use of the resin as a mask, to make an end portion of the resin recede by ashing, and to etch the first inorganic film.

In this case, the eighth cluster can include the fourth dry etching apparatus, one of a dry etching apparatus with an ashing function and an ashing apparatus, and the first wet etching apparatus. Alternatively, the eighth cluster may include the first wet etching apparatus, one of the dry etching apparatus with an ashing function and the ashing function, and the second wet etching apparatus.

The equipment for manufacturing a light-emitting device and a light-receiving device can further include a ninth cluster, and the ninth cluster is connected to the eighth cluster through an eighth buffer chamber. The ninth cluster can be configured to form a conductive layer and an insulating layer over the light-emitting layer and the photoelectric conversion layer.

The ninth cluster can includes at least two of an evaporation apparatus, a sputtering apparatus, and an ALD apparatus.

With one embodiment of the present invention, equipment for manufacturing a light-emitting device and a light-receiving device, with which steps from processing to sealing of an organic compound film in the devices can be continuously performed, can be provided. Alternatively, equipment for manufacturing a light-emitting device and a light-receiving device, with which steps from processing to sealing of the devices can be continuously performed, can be provided. Alternatively, equipment for manufacturing a light-emitting device and a light-receiving device, which enables formation of the devices without a metal mask, can be provided. Alternatively, a method for manufacturing a light-emitting device and a light-receiving device can be provided.

Note that the description of these effects does not preclude the existence of other effects. One embodiment of the present invention does not necessarily have all the effects listed above. Effects other than these can be derived from the description of the specification, the drawings, the claims, and the like.

### BRIEF DESCRIPTION OF THE DRAWINGS

FIG. 1 illustrates manufacturing equipment.

FIGS. 2A and 2B each illustrate manufacturing equipment.

FIG. 3 illustrates manufacturing equipment.

FIG. 4 illustrates manufacturing equipment.

FIG. 5 is a block diagram illustrating manufacturing equipment.

FIGS. 6A and 6B each illustrate manufacturing equipment.

FIGS. 7A and 7B each illustrate manufacturing equipment.

FIG. 8 illustrates manufacturing equipment.

FIG. 9 is a block diagram illustrating manufacturing equipment.

FIGS. 10A and 10B each illustrate manufacturing equipment.

FIGS. 11A and 11B each illustrate a state of carrying in/out of a cassette. FIG. 11C illustrates a delivery vehicle and a delivery container.

FIG. 12A illustrates a vacuum processing apparatus. FIG. 12B illustrates the transfer of a substrate into the vacuum processing apparatus.

FIGS. 13A to 13C each illustrate an example of the number of display devices taken out from one substrate.

FIGS. 14A to 14H each illustrate a vacuum processing apparatus.

FIG. 15 illustrates a display device.

FIGS. 16A to 16C each illustrate a display device.

FIGS. 17A to 17E illustrate a method for manufacturing a display device.

FIGS. 18A to 18E illustrate a method for manufacturing a display device.

FIGS. 19A to 19E illustrate a method for manufacturing a display device.

FIGS. 20A to 20E illustrate a method for manufacturing a display device.

FIGS. 21A to 21E illustrate a method for manufacturing a display device.

FIG. 22 illustrates manufacturing equipment.

FIGS. 23A and 23B are graphs for describing film quality of an AlOx film deposited with an ALD apparatus.

FIGS. 24A and 24B are graphs for describing film quality of an AlOx film deposited with an ALD apparatus.

### DETAILED DESCRIPTION OF THE INVENTION

Embodiments will be described in detail with reference to the drawings. However, the present invention is not limited to the following description, and it is readily appreciated by those skilled in the art that modes and details can be modified in various ways without departing from the spirit and the scope of the present invention. Therefore, the present invention should not be interpreted as being limited to the descriptions of embodiments below. Note that in structures of the invention described below, the same portions or portions having similar functions are denoted by the same reference numerals in different drawings, and the description thereof is not repeated in some cases. The same components are denoted by different hatching patterns in different drawings, or the hatching patterns are omitted in some cases.

### Embodiment 1

In this embodiment, equipment for manufacturing a light-emitting device and a light-receiving device of one embodiment of the present invention will be described with reference to drawings.

One embodiment of the present invention is manufacturing equipment used for forming a display device in which a light-emitting device (also referred to as light-emitting element) and a light-receiving device (also referred to as light-receiving element) each include an organic compound layer and are provided in a pixel portion. It is preferable to use a lithography step in order to downscale the light-emitting device and the light-receiving device and to increase their areas occupied in pixels. However, the reliability of the display device is impaired when impurities such as water, oxygen, and hydrogen enter the organic compound layer. Therefore, some ingenuity is necessary. For example, patterned organic compound layers are sealed so that their top surfaces and side surfaces are not exposed to the air, and the atmosphere for the manufacturing process is controlled to have a low dew point.

The side surfaces of the organic compound layers are preferably sealed with an inorganic insulating layer and an organic insulating layer. In particular, the organic insulating layer is formed to fill a space between the organic compound layers, whereby disconnection of electrodes formed over the organic compound layers can be prevented. With the manufacturing equipment of one embodiment of the present invention, the inorganic insulating layer and the organic insulating layer that seal the side surfaces of the organic compound layers can be formed in continuous steps so that the top surfaces and side surfaces of the patterned organic compound layers are prevented from being exposed to the air. Note that in this specification and the like, disconnection refers to a phenomenon in which a layer, a film, or an electrode is split because of the shape of the formation surface (e.g., a level difference).

Furthermore, the manufacturing equipment of one embodiment of the present invention enables a film-formation step for forming the light-emitting device and the light-receiving device, a sealing step, and the like, in addition to the above steps, to be continuously performed. Thus, alight-emitting device and alight-receiving device each of which is minute and has high reliability can be formed. Moreover, the manufacturing equipment of one embodiment of the present invention can have an in-line system where apparatuses are arranged according to the order of process steps for the light-emitting device and the light-receiving device, resulting in high throughput manufacturing.

A silicon wafer can be used as a support substrate for forming the light-emitting device and the light-receiving device. A silicon wafer where a driver circuit, a pixel circuit, and the like are formed in advance is used as a support substrate, and the light-emitting device and the light-receiving device can be formed over these circuits. Thus, a display device with a narrow frame, which is suitable for AR or VR, can be formed. The silicon wafer is preferably φ8 inches or more (e.g., φ12 inches). Note that the support substrate for forming the light-emitting device and the light-receiving device is not limited to the above. For example, glass, quartz, ceramics, sapphire, a resin, a metal, an alloy, or a semiconductor (e.g., GaAs) can be used for the support substrate over which the light-emitting device and the light-receiving device are formed.

### Structure Example 1

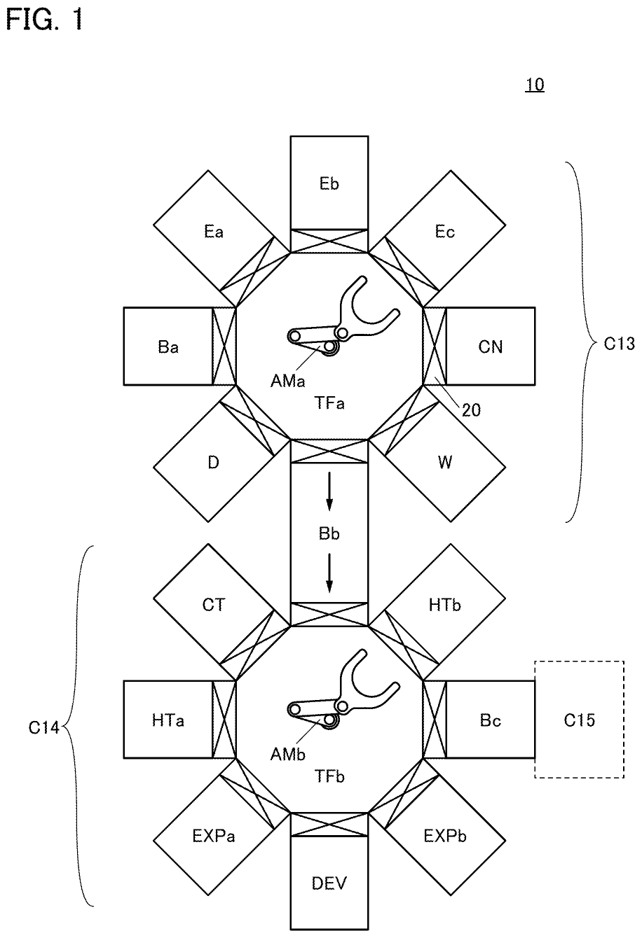

FIG. 1 illustrates manufacturing equipment 10 for a light-emitting device and a light-receiving device of one embodiment of the present invention. The manufacturing equipment 10 enables a step of processing an organic compound film into island-shaped organic compound layers, a step of forming a layer protecting side surfaces of the island-shaped organic compound layers and a step of forming an organic insulating layer between the island-shaped organic compound layers, in a fabrication process of the light-emitting device and the light-receiving device. The above steps are continuously performed, whereby the side surfaces of the organic compound layers can be sealed without being exposed to the air. Accordingly, highly reliable light-emitting device and light-receiving device can be formed.

Note that in this specification and the like, the term “island shape” refers to a state where two or more layers formed using the same material in the same step are physically separated from each other. For example, an island-shaped organic compound layer means a state where the organic compound layers adjacent to each other are physically separated from each other.

Into the manufacturing equipment 10, a substrate provided with a stacked film including an organic compound film, a first inorganic film, and a second inorganic film and a resist mask formed over the stacked film can be brought as an object to be processed.

Note that the organic compound film can be an organic compound film for forming a light-emitting device or a light-receiving device.

The substrate provided with a third inorganic film and an organic insulating layer covering side surfaces of island-shaped organic compound layers can be taken out from a chamber corresponding to an unload chamber of the manufacturing equipment 10. A film-formation apparatus and the like for forming an organic compound layer or a conductive layer (common electrode) provided on top surfaces of the organic compound layers can be connected to the chamber corresponding to an unload chamber of the manufacturing equipment 10.

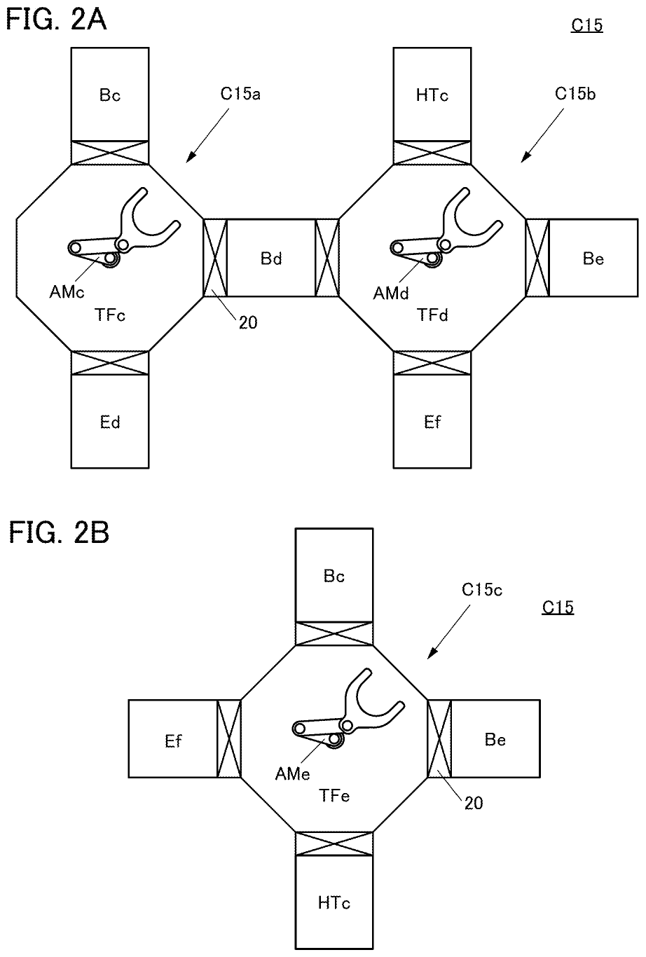

The manufacturing equipment 10 includes a cluster C13, a cluster C14, and a cluster C15. In this specification, a group of apparatuses which shares a delivery device or the like is called a cluster. The clusters are connected through a buffer chamber. Structure examples of the cluster C13 and the cluster C14 are illustrated in FIG. 1, and a structure example of the cluster C15 is illustrated in FIGS. 2A and 2B, FIG. 3, and FIG. 4.

The cluster C13 includes an apparatus performing processing under reduced pressure. The cluster C14 includes an apparatus performing processing under normal pressure. The cluster C15 includes an apparatus performing processing under reduced pressure and an apparatus performing processing under normal pressure. Note that the cluster C15 can have a structure without an apparatus performing processing under reduced pressure.

The kinds and number of chambers and apparatuses included in the clusters shown in this embodiment are typical examples, and there is no limitation on the kinds and number thereof. For example, one cluster may include two or more of the same apparatus for the purpose of a throughput improvement. When a stacked film is formed, there are a case of forming the stacked film in one film-formation apparatus and a case of forming the stacked film with a plurality of film-formation apparatuses. For example, even when one film-formation apparatus is illustrated in one cluster, the cluster may have a structure with a plurality of film-formation apparatuses. Moreover, the plurality of film-formation apparatuses may be different kinds of apparatuses.

As for steps performed in the clusters, details will be described in an example of manufacturing method of a light-emitting device and a light-receiving device and an example of manufacturing equipment shown in Embodiment 2.

### <Cluster C13>

The cluster C13 is a group of apparatuses for processing a stacked film including an organic compound film, a first inorganic film, and a second organic film into island shapes and covering organic compound layers and the first inorganic film with a third inorganic film. The cluster C13 includes a buffer chamber Ba, a buffer chamber Bb, a standby chamber W, a transfer chamber TFa, and a plurality of treatment chambers. The transfer chamber TFa is provided with a delivery device AMa.

The buffer chamber Ba corresponds to a load chamber in the cluster C13. The buffer chamber Bb corresponds to an unload chamber in the cluster C13. The buffer chamber Bb is shared with the cluster C14.

The buffer chamber Ba, the buffer chamber Bb, the standby chamber W, and the plurality of treatment chambers are connected to the transfer chamber TFa through respective gate valves 20.

The delivery device AMa can transfer the object to be processed from any one of the buffer chamber Ba, the buffer chamber Bb, the standby chamber W, and the plurality of treatment chambers to another of them.

When the manufacturing equipment is activated, the buffer chamber Ba and the buffer chamber Bb are controlled under reduced pressure or normal pressure. Under the normal pressure control, an inert gas with a low dew point is preferably introduced. The transfer chamber TFa, the standby chamber W, and the plurality of treatment chambers are controlled under reduced pressure.

As the plurality of treatment chambers, an etching apparatus Ea, an etching apparatus Eb, an etching apparatus Ec, a plasma treatment apparatus CN, a film-formation apparatus D, and the like can be employed, for example. The objected to be processed, which is taken into the manufacturing equipment, can includes a stacked body in which an organic compound film, a first inorganic film, a second inorganic film, and a resist mask are stacked in this order, for example.

The etching apparatus Ea can be a dry etching apparatus. The etching apparatus Ea can be used for a step of processing the first inorganic film and the second inorganic film into island shapes.

The etching apparatus Eb can be a dry etching apparatus. The etching apparatus Eb can be used for a step of processing the organic compound film into island-shaped organic compound layers with use of the island-shaped first and second inorganic films as masks. The etching apparatus Eb may have an ashing function. With the ashing function, the resist mask can be removed.

The etching apparatus Ec can be a dry etching apparatus. The etching apparatus Ec can be used for a step of removing the second inorganic film used as the mask.

Although the above-described mode is an example in which the etching apparatus Eb has an ashing function, the etching apparatus Ea or Ec may have an ashing function instead. Although components to be processed are distinguished between the etching apparatuses Ea to Ec in the above description, all of the processing described above may be continuously performed in the etching apparatuses Ea to Ec.

The plasma treatment apparatus CN includes a pair of electrodes of a parallel-plate type, for example, and voltage is applied between the electrodes in an inert gas atmosphere under reduced pressure, whereby plasma can be generated. The object to be processed is irradiated with plasma generated from the inert gas, so that a reaction product, an absorbed gas, and the like remaining on the surface of the object to be processed can be removed. Examples of the inert gas to be used include a high-purity noble gas such as helium, argon, or neon, nitrogen, or a mixed gas thereof.

Either before or after the above plasma treatment, vacuum baking treatment is preferably performed in the same apparatus, thereby removing water absorbed on the surface. The vacuum baking is preferably performed within such a temperature range that the organic compound layers do not deteriorate, and for example, the temperature condition can be set to be higher than or equal to 70° C. and lower than or equal to 120° C., preferably higher than or equal to 80° C. and lower than or equal to 100° C. Note that the baking vacuum treatment may be performed in the film-formation apparatus D before a film formation step that is the next step. The manufacturing equipment can have a structure without the plasma treatment apparatus CN.

The standby chamber W can make a plurality of objects to be processed be in a standby state. For example, in the case where the film-formation apparatus D has a batch processing system, the plurality of objects to be processed are made to be in a standby state in the standby chamber W after treatments performed in the etching apparatuses Ea to Ec and the plasma treatment apparatus CN are finished, whereby the throughput can be improved. In the case where the film-formation apparatus D has a single-wafer processing system, the manufacturing equipment can have a structure without the standby chamber W.

A plurality of the standby chambers W may be provided. For example, the standby chambers W may be provided so that the objects to be processed are made in a standby state after the batch processing in the film-formation apparatus D. All of the objects to be processed are taken out from the film-formation apparatus D, in which case the film-formation apparatus D has no objects standing by, and the throughput of the film-formation apparatus D can be improved.

As the film-formation apparatus D, a film-formation apparatus such as an evaporation apparatus, a sputtering apparatus, a chemical vapor deposition (CVD) apparatus, or an atomic layer deposition (ALD) apparatus can be employed. In particular, an ALD apparatus enabling film formation with good coverage is preferably used. With the film-formation apparatus D, the third inorganic film (protective film) covering the island-shaped organic compound layers and the island-shaped first inorganic films can be formed. With the film-formation apparatus D, not only a single layer but also two or more layers that are different kinds can be formed. The film-formation apparatus D may have a single-wafer processing system, not being limited to the batch processing system.

### <Cluster C14>

The cluster C14 is a group of apparatuses for forming an organic insulating layer between the island-shaped organic compound layers. The cluster C14 includes the buffer chamber Bb, a buffer chamber Bc, a transfer chamber TFb, and a plurality of treatment chambers. The transfer chamber TFb is provided with a delivery device AMb. The buffer chamber Bb corresponds to a load chamber in the cluster C14. The buffer chamber Bc corresponds to an unload chamber in the cluster C14. The cluster C14 is connected to the cluster C13 through the buffer chamber Bb.

The buffer chamber Bb, the buffer chamber Bc, and the plurality of treatment chambers are connected to the transfer chamber TFb through the respective gate valves 20.

The delivery device AMb can transfer the object to be processed from any one of the buffer chamber Bb, the buffer chamber Bc, and the plurality of treatment chambers to another of them.

When the manufacturing equipment is activated, the buffer chamber Bc is controlled under reduced pressure or normal pressure. The transfer chamber TFb and the plurality of treatment chambers are controlled under normal pressure. The controlled pressures in the transfer chamber TFb and the plurality of treatment chambers are not limited to the normal pressure but may be the negative or positive pressure to some extent compared to the normal pressure. Furthermore, the atmospheric pressures in the transfer chamber TFb and the plurality of treatment chambers may be different from each other.

The transfer chamber TFb and the plurality of treatment chambers can be controlled in an inert gas atmosphere. Examples of the inert gas that can be used include nitrogen or a noble gas such as argon or helium. In addition, the inert gas preferably has a low dew point (e.g., −50° C. or lower). An atmosphere of an inert gas with a low dew point is employed for process steps, whereby highly reliable light-emitting devices and light-receiving devices where entry of impurities are prevented can be formed.

As the plurality of treatment chambers, for example, a coating apparatus CT, a baking apparatus HTa, a light-exposure apparatus EXPa, a development apparatus DEV, a light-exposure apparatus EXPb, a baking apparatus HTb, and the like can be employed.

As the coating apparatus CT, an apparatus for performing coating of a resin to be an organic insulating layer by a method such as spin coating, dipping, spray coating, ink-jetting, dispensing, screen printing, offset printing, or with a tool such as a doctor knife, a slit coater, a roll coater, a curtain coater, or a knife coater, for example. For the resin, a photosensitive resin such as an ultraviolet curable resin can be used.

As the baking apparatus HTa, a hot plate-type or oven-type baking apparatus can be employed. The baking apparatus HTa can be used for pre-baking of a resin used for coating.

As the light-exposure apparatus EXPa and the development apparatus DEV, a light-exposure apparatus and a development apparatus for performing a photolithography step can be employed. In the case of using a positive photosensitive resin, the resin is partly exposed to light with the light-exposure apparatus EXPa and developed with the development apparatus DEV, so that the resin in the exposed region can be removed. Through this step, a resin (organic insulating layer) can be formed between the island-shaped organic compound layers.

As the light-exposure apparatus EXPb, a light-exposure apparatus same as the light-exposure apparatus EXPa can be used. Alternatively, a lamp apparatus with a simple structure, which emits ultraviolet light, may be used. In the light-exposure apparatus EXPb, ultraviolet irradiation is performed on the resin remaining after the development step.

Since the organic compound layer has low heat resistance, the temperature at post-baking a resin is preferably as low as possible. The curing reaction of the resin is promoted through light exposure, in which case the post-baking temperature in the next step can be reduced in some cases depending on a resin material. Thus, it is preferable that the light exposure step be performed with the light-exposure apparatus EXPb in some cases. Note that depending on a resin material, a light exposure step is not necessarily performed, in which case the light-exposure apparatus EXPb is not needed.

As the baking apparatus HTb, a baking apparatus same as the baking apparatus HTa can be used. In the baking apparatus HTb, the resin (organic insulating layer) formed between the island-shaped organic compound layers are reflowed and cured. At a stage after the above development step, the resin has a steep side surface, and an appropriate corner shape is made between the top surface and side surface of the resin. The baking treatment performed in the baking apparatus HTb makes the resin to be reflowed, and the approximate corner shape is changed to have a curved surface. By a change in shape of the resin in the above manner, the coverage with a conductive layer formed over a plurality of island-shaped organic compound layers is improved, so that disconnection can be prevented. This baking step is also referred to as post baking.

### <Cluster C15>

The cluster C15 is a group of apparatuses for etching the first inorganic film and the third inorganic film remaining on the organic compound layers. The first inorganic film and the third inorganic film are etched with use of the resin (organic insulating layer) formed in the cluster C14 as a mask; however, when the etching excessively proceeds, a hollow may be generated in the lower part of the resin. The appropriate process differs depending on materials and thicknesses of the first inorganic film and the third inorganic film. Accordingly, a plurality of structures are applicable to apparatuses in the cluster C15. Note that in the description below, chambers, apparatuses, and the like, which have the same structures as the above, are denoted by the same reference numerals in some cases.

### Application Example 1

FIG. 2A illustrates Application Example 1 of a group of apparatuses applicable to the cluster C15. The structure illustrated in FIG. 2A is for etching the first inorganic film and the third inorganic film remaining on the organic compound layer. Specifically, the third inorganic film is first subjected to dry etching, and the first inorganic film is subjected to wet etching.

The cluster C15 illustrated in FIG. 2A includes a cluster C15a and a cluster C15b.

The cluster C15a is a group of apparatuses for mainly etching the third inorganic film. The cluster C15a includes the buffer chamber Bc, a buffer chamber Bd, a transfer chamber TFc, and an etching apparatus Ed. The transfer chamber TFc is provided with a delivery device AMc.

The buffer chamber Bc corresponds to a load chamber in the cluster C15a. The buffer chamber Bd corresponds to an unload chamber in the cluster C15a. The cluster C15a is connected to the cluster C14 through the buffer chamber Bc.

The buffer chamber Bc, the buffer chamber Bd, and the etching apparatus Ed are connected to the transfer chamber TFc through respective gate valves 20.

The delivery device AMc can transfer the object to be processed from any one of the buffer chamber Bc, the buffer chamber Bd, and the etching apparatus Ed to another of them.

When the manufacturing equipment is activated, the buffer chamber Bd is controlled under reduced pressure or normal pressure. Under the normal pressure control, an inert gas with a low dew point is preferably introduced. The transfer chamber TFc and the etching apparatus Ed are controlled under reduced pressure.

A dry etching apparatus can be used for the etching apparatus Ed. The etching apparatus Ed can be used in a step of etching the third inorganic film mainly. In this step, the etching of the third inorganic film is performed with use of the organic insulating layer as a mask; thus, anisotropic etching is preferably performed so as not to generate a hollow below the organic insulating layer.

The cluster C15b is a group of apparatuses for etching the first inorganic film mainly. The cluster C15b includes the buffer chamber Bd, a buffer chamber Be, a transfer chamber TFd, an etching apparatus Ef, and a baking apparatus HTc. The transfer chamber TFd is provided with a delivery device AMd.

The buffer chamber Bd corresponds to a load chamber in the cluster C15b. The buffer chamber Be corresponds to an unload chamber in the cluster C15b. The cluster C15b is connected to the cluster C15a through the buffer chamber Bd.

The buffer chamber Bd, the buffer chamber Be, the etching apparatus Ef, and the baking apparatus HTc are connected to the transfer chamber TFd through respective gate valves 20.

The delivery device AMd can transfer the object to be processed from any one of the buffer chamber Bd, the buffer chamber Be, the etching apparatus Ef, and the baking apparatus HTc to another of them.

When the manufacturing equipment is activated, the buffer chamber Be is controlled under reduced pressure or normal pressure. The transfer chamber TFd, the etching apparatus Ef, and the baking apparatus HTc are controlled under normal pressure. Under the normal pressure control, an inert gas with a low dew point is preferably introduced.

A wet etching apparatus can be used for the etching apparatus Ef. The etching apparatus Ef can be used in a step of etching the first inorganic film mainly. Here, the first inorganic film is provided in contact with the organic compound layer that easily suffers from plasma damage. Thus, the first inorganic film is preferably removed by wet etching.

As the baking apparatus HTc, a hot plate-type or oven-type baking apparatus can be employed. The baking apparatus HTc can be used for drying the object to be processed after the wet etching step.

### Application Example 2

FIG. 2B illustrates Application Example 2 of a group of apparatuses applicable to the cluster C15. The structure illustrated in FIG. 2B is for etching the first inorganic film and the third inorganic film remaining on the organic compound layer. Specifically, both of the films are subjected to wet etching. Wet etching treatment is performed on both the first inorganic film and the third inorganic film, which enables the simplification of the apparatus structure, an improvement in throughput, and the absence of plasma damage to the organic compound layer.

The cluster C15 illustrated in FIG. 2B includes a cluster C15c.

The cluster C15c is a group of apparatuses for etching the first inorganic film and the third inorganic film mainly. The cluster C15c includes the buffer chamber Bc, the buffer chamber Be, a transfer chamber TFe, the etching apparatus Ef, and the baking apparatus HTc. The transfer chamber TFc is provided with a delivery device AMe.

The buffer chamber Bc corresponds to a load chamber in the cluster C15c. The buffer chamber Be corresponds to an unload chamber in the cluster C15c. The cluster C15c is connected to the cluster C14 through the buffer chamber Bc.

The buffer chamber Bc, the buffer chamber Be, the etching apparatus Ef, and the baking apparatus HTc are connected to the transfer chamber TFe through respective gate valves 20.

The delivery device AMe can transfer the object to be processed to any one of the buffer chamber Bd, the buffer chamber Be, the etching apparatus Ef, and the baking apparatus HTc to another of them.

When the manufacturing equipment is activated, the buffer chamber Be is controlled under reduced pressure or normal pressure. The transfer chamber TFe, the etching apparatus Ef, and the baking apparatus HTc are controlled under normal pressure. Under the normal pressure control, an inert gas with a low dew point is preferably introduced.

A wet etching apparatus can be used for the etching apparatus Ef. The etching apparatus Ef can be used in a step of etching the first inorganic film and the third inorganic film mainly.

As the baking apparatus HTc, a hot plate-type or oven-type baking apparatus can be employed. The baking apparatus HTc can be used for drying the object to be processed after the wet etching step.

### Application Example 3

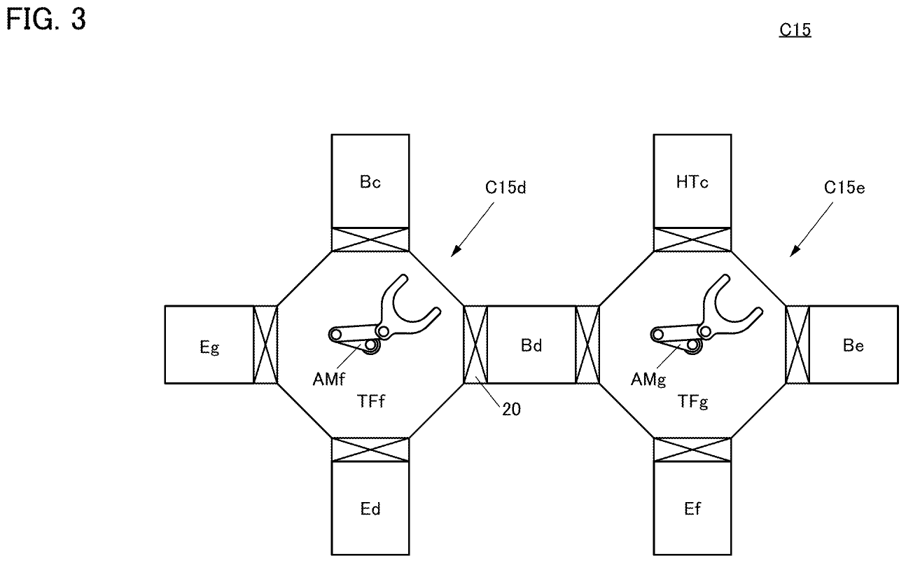

FIG. 3 illustrates Application Example 3 of a group of apparatuses applicable to the cluster C15. The structure illustrated in FIG. 3 is for etching the first inorganic film and the third inorganic film. Specifically, the third inorganic film is first subjected to dry etching, part of the organic insulating layer that serves as a mask is subjected to ashing, and the first inorganic film is subjected to wet etching.

The organic insulating layer is subjected to ashing to have recessed end portions before wet etching of the first inorganic film, whereby the third inorganic film in a region overlapping with the organic insulating layer can be exposed. After that, the first inorganic layer and the exposed third inorganic film are subjected to wet etching using the organic insulating layer as a mask, so that a hollow can be less likely to be generated below the organic insulating layer.

The cluster C15 illustrated in FIG. 3 includes a cluster C15d and a cluster C15e.

The cluster C15d is a group of apparatuses for etching the etching the third inorganic film and performing ashing on the organic insulating layer mainly. The cluster C15d includes the buffer chamber Bc, the buffer chamber Bd, a transfer chamber TFf, the etching apparatus Ed, and an etching apparatus Eg. The transfer chamber TFf is provided with a delivery device AMf.

The buffer chamber Bc corresponds to a load chamber in the cluster C15d. The buffer chamber Bd corresponds to an unload chamber in the cluster C15d. The cluster C15d is connected to the cluster C14 through the buffer chamber Bc.

The buffer chamber Bc, the buffer chamber Bd, the etching apparatus Ed, and the etching apparatus Eg are connected to the transfer chamber TFf through respective gate valves 20.

The delivery device AMf can transfer the object to be proceeded from any one of the buffer chamber Bc, the buffer chamber Bd, the etching apparatus Ed, and the etching apparatus Eg to another of them.

When the manufacturing equipment is activated, the buffer chamber Bd is controlled under reduced or normal pressure. Under the normal pressure control, an inert gas with a low dew point is preferably introduced. The transfer chamber TFf, the etching apparatus Ed, and the etching apparatus Eg are controlled under reduced pressure.

A dry etching apparatus can be used for the etching apparatus Ed. The etching apparatus Ed can be used in a step of etching the third inorganic film mainly. In this step, the etching of the third inorganic film is performed with use of the organic insulating layer as a mask; thus, anisotropic etching is preferably performed so as not to generate a hollow below the organic insulating layer.

As the etching apparatus Eg, a dry etching apparatus having an ashing function or an ashing apparatus can be employed. The etching apparatus Eg can be used in a step of making the end portion of the organic insulating layer that serves as a mask in etching of the first inorganic film and the third inorganic film mainly to be recessed.

Although the above example shows the structure where the etching apparatus Ed and the etching apparatus Eg are separately provided, the dry etching and the ashing may be continuously performed in the etching apparatus Eg. In this case, the etching apparatus Ed can be omitted.

The cluster C15e is a group of apparatuses for etching the first inorganic film mainly. The cluster C15e includes the buffer chamber Bd, the buffer chamber Be, a transfer chamber TFg, the etching apparatus Ef, and the baking apparatus HTc. The transfer chamber TFg is provided with a delivery device AMg.

The buffer chamber Bd corresponds to a load chamber in the cluster C15e. The buffer chamber Be corresponds to an unload chamber in the cluster C15e. The cluster C15e is connected to the cluster C15d through the buffer chamber Bd.

The buffer chamber Bd, the buffer chamber Be, the etching apparatus Ef, and the baking apparatus HT are connected to the transfer chamber TFg through respective gate valves 20.

The delivery device AMg can transfer the object to be processed from any one of the buffer chamber Bd, the buffer chamber Be, the etching apparatus Ef, and the baking apparatus HTc to another of them.

When the manufacturing equipment is activated, the buffer chamber Be is controlled under reduced or normal pressure. The transfer chamber TFg, the etching apparatus Ef, and the baking apparatus HTc are controlled under normal pressure. Under the normal pressure control, an inert gas with a low dew point is preferably introduced.

A wet etching apparatus can be used for the etching apparatus Ef. The etching apparatus Ef can be used in a step of etching the first inorganic film mainly.

As the baking apparatus HTc, a hot plate-type or oven-type baking apparatus can be employed. The baking apparatus HTc can be used for drying the object to be processed after the wet etching step.

### Application Example 4

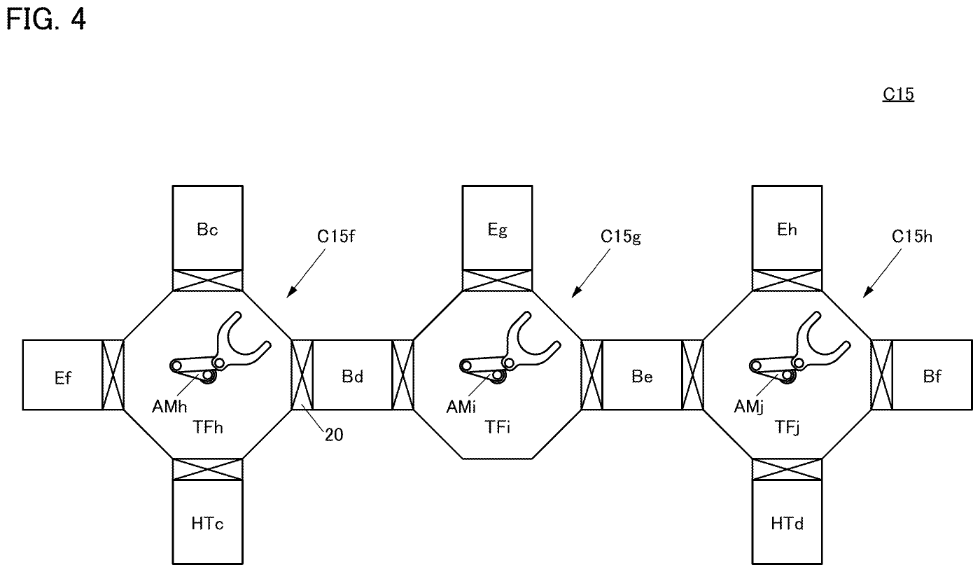

FIG. 4 illustrates Application Example 4 of a group of apparatuses applicable to the cluster C15. The structure illustrated in FIG. 4 is for etching the first inorganic film and the third inorganic film remaining on the organic compound layer. Specifically, the third inorganic film is subjected to wet etching first, part of the organic insulating layer that serves as a mask is subjected to ashing, and the first inorganic film is subjected to wet etching.

The organic insulating layer is subjected to ashing to have recessed end portions before wet etching of the first inorganic film, whereby a hollow can be less likely to be generated below the organic insulating layer. The third inorganic film is subjected to wet etching; thus the apparatus structure is different from that in Application Example 3.

The cluster C15 illustrated in FIG. 4 includes a cluster C15f, a cluster C15g, and a cluster C15h.

The cluster C15f is a group of apparatuses for etching the third inorganic film mainly. The cluster C15f includes the buffer chamber Bc, the buffer chamber Bd, a transfer chamber TFh, the etching apparatus Ef, and the baking apparatus HTc. The transfer chamber TFh is provided with a delivery device AMh.

The buffer chamber Bc corresponds to a load chamber in the cluster C15f. The buffer chamber Bd corresponds to an unload chamber in the cluster C15f. The cluster C15f is connected to the cluster C14 through the buffer chamber Bc.

The buffer chamber Bc, the buffer chamber Bd, the etching apparatus Ef, and the baking apparatus HTc are connected to the transfer chamber TFh through respective gate valves 20.

The delivery device AMh can transfer the object to be proceeded from any one of the buffer chamber Bc, the buffer chamber Bd, the etching apparatus Ef, and the baking apparatus HTc to another of them.

When the manufacturing equipment is activated, the buffer chamber Bd is controlled under reduced or normal pressure. The transfer chamber TFh, the etching apparatus Ef, and the baking apparatus HTc are controlled under normal pressure. Under the normal pressure control, an inert gas with a low dew point is preferably introduced.

A wet etching apparatus can be used for the etching apparatus Ef. The etching apparatus Ef can be used in a step of etching the third organic insulating film mainly.

As the baking apparatus HTc, a hot plate-type or oven-type baking apparatus can be employed. The baking apparatus HTc can be used for drying the object to be processed after the wet etching step.

The cluster C15g is a group of apparatuses for ashing of the organic insulating layer mainly. The cluster C15g includes the buffer chamber Bd, the buffer chamber Be, a transfer chamber TFi, and the etching apparatus Eg. The transfer chamber TFi is provided with a delivery device AMi.

The buffer chamber Bd corresponds to a load chamber in the cluster C15g. The buffer chamber Be corresponds to unload chamber in the cluster C15g. The cluster C15g is connected to the cluster C15f through the buffer chamber Bd.

The buffer chamber Bd, the buffer chamber Be, and the etching apparatus Eg are connected to the transfer chamber TFi through respective gate valves 20.

The delivery device AMi can transfer the object to be processed from any one of the buffer chamber Bd, the buffer chamber Be, and the etching apparatus Eg to another one of them.

When the manufacturing equipment is activated, the buffer chamber Be is controlled under reduced or normal pressure. Under the normal pressure control, an inert gas with a low dew point is preferably introduced. The transfer chamber TFi and the etching apparatus Eg are controlled under reduced pressure.

As the etching apparatus Eg, a dry etching apparatus having an ashing function or an ashing apparatus can be employed. The etching apparatus Eg can be used in a step of making the end portion of the organic insulating layer that serves as a mask to be recessed.

The cluster C15h is a group of apparatuses for etching the first inorganic film mainly. The cluster C15h includes the buffer chamber Be, a buffer chamber Bf, a transfer chamber TFj, an etching apparatus Eh, and a baking apparatus HTd. The transfer chamber TFj is provided with a delivery device AMj.

The buffer chamber Be corresponds to a load chamber in the cluster C15h. The buffer chamber Bf corresponds to an unload chamber in the cluster C15h. The cluster C15h is connected to the cluster C15g through the buffer chamber Be.

The buffer chamber Be, the buffer chamber Bf, the etching apparatus Eh, and the baking apparatus HTd are connected to the transfer chamber TFg through respective gate valves 20.

The delivery device AMj can transfer the object to be processed from any one of the buffer chamber Be, the buffer chamber Bf, the etching apparatus Eh, and the baking apparatus HTd to another of them.

When the manufacturing equipment is activated, the buffer chamber Bf is controlled under reduced or normal pressure. The transfer chamber TFj, the etching apparatus Eh, and the baking apparatus HTd are controlled under normal pressure. Under the normal pressure control, an inert gas with a low dew point is preferably introduced.

A wet etching apparatus can be used for the etching apparatus Eh. The etching apparatus Eh can be used in a step of etching the first inorganic film mainly.

As the baking apparatus HTc, a hot plate-type or oven-type baking apparatus can be employed. The baking apparatus HTc can be used for drying the object to be processed after the wet etching step.

Note that in Application Examples 1 to 4 of the cluster C15 described above, the first inorganic film and the third inorganic film may be formed using the same material. Even when the first inorganic film and the third inorganic film are formed using different materials, the etching selectivity is not so high in some cases. Therefore, the third inorganic film is partly etched in etching of the first inorganic film in some cases. Alternatively, part of the third inorganic film can be intentionally etched in etching of the first inorganic film.

### Structure Example 2

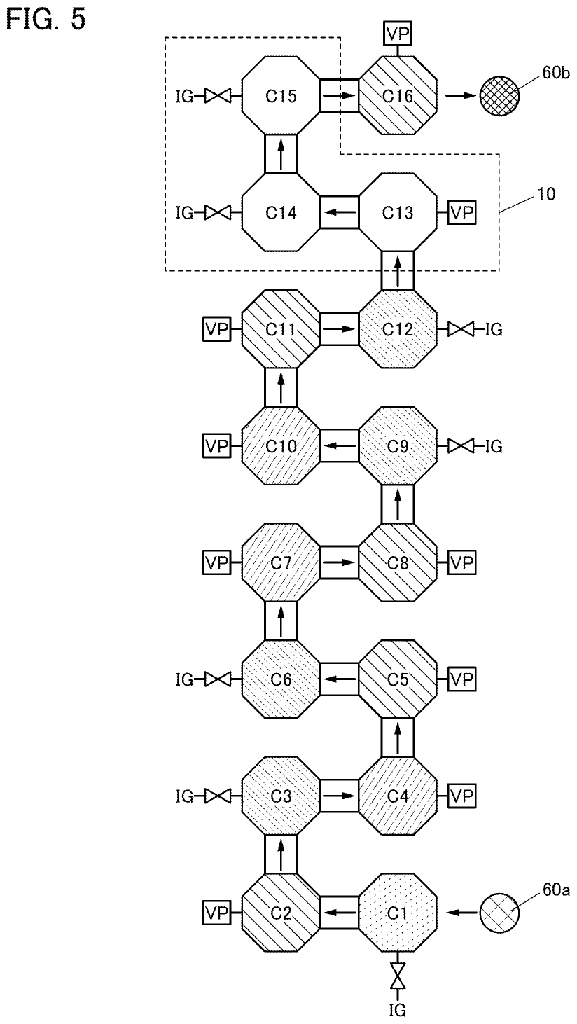

FIG. 5 is a block diagram illustrating manufacturing equipment for a light-emitting device of and a light-receiving device of one embodiment of the present invention. The manufacturing equipment includes a plurality of clusters arranged in the order of process steps, in which the manufacturing equipment 10 (the clusters C13 to C15) with Structure Example 1 described above is included. A substrate where the light-emitting device and the light-receiving device are formed is moved between the plurality of clusters in sequence, so that the steps are conducted.

The manufacturing equipment illustrated in FIG. 5 is an example including clusters C1 to C16. The clusters C1 to C16 are sequentially connected through buffer chambers. An object to be processed 60a taken into the cluster C1 can be taken out, from the cluster C16, as a processed object 60b where the light-emitting device is formed. Note that another cluster can be connected in front of or behind the clusters C1 to C16.

The clusters C1, C3, C6, C9, C12, C14, and C15 each include a group of apparatuses for performing a process under atmosphere control. The clusters C2, C4, C5, C7, C8, C10, C11, C13, and C16 each include a group of apparatuses for performing vacuum processing (process under reduced pressure).

The cluster C1 includes apparatuses mainly for cleaning and baking the object to be processed, and the like. The clusters C2, C5, C8, and C11 each include apparatuses mainly for forming an organic compound included in the light-emitting device or the light-receiving device, and the like. The clusters C3, C6, C9, and C12 each include apparatuses mainly for performing a lithography step, and the like. The clusters C4, C7, C10, and C15 each include apparatuses mainly for performing an etching step or an ashing step, and the like. The cluster C16 includes apparatuses mainly for forming an organic compound included in the light-emitting device and the light-receiving device and forming a protective film to seal the light-emitting device and the light-receiving device, and the like. The clusters C13 to C15 includes apparatuses described in Structure Example 1, and the like.

Next, the details of the clusters C1 to C9 and C16 are described. Note that the buffer chamber, the transfer chamber, and the delivery device are described with use of the common reference numerals.

### <Cluster C1>

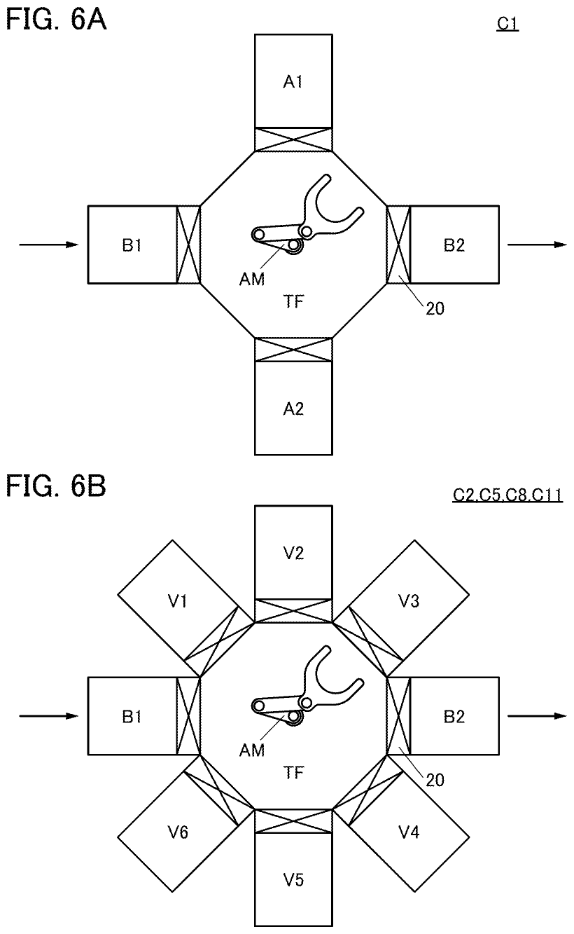

FIG. 6A is a top view illustrating the apparatus structure applicable to the cluster C1. The cluster C1 is a group of apparatuses for performing a cleaning step. The cluster C1 includes a buffer chamber B1 corresponding to a load chamber, a buffer chamber B2 corresponding to an unload chamber, a transfer chamber TF, and a plurality of normal-pressure processing apparatuses A. The transfer chamber TF is provided with a delivery device AM.

The buffer chamber B1, the buffer chamber B2, and the plurality of normal-pressure processing apparatuses A are connected to the transfer chamber TF through respective gate valves 20.

The delivery device AM can transfer the object to be processed from any one of the buffer chamber B1, the buffer chamber B2, and the plurality of normal-pressure processing apparatuses A to another of them.

When the manufacturing equipment is activated, the buffer chambers B1 and B2 are controlled under reduced pressure or normal pressure. The transfer chamber TF and the plurality of normal-pressure processing apparatuses A are controlled under normal pressure. Under the normal pressure control, an inert gas with a low dew point is preferably introduced.

A valve for introducing an inert gas (IG) is connected to the cluster C1 (see FIG. 5); accordingly, the cluster C1 can be controlled in an inert gas atmosphere. Examples of the inert gas that can be used include nitrogen or a noble gas such as argon or helium. In addition, the inert gas preferably has a low dew point (e.g., −50° C. or lower). An atmosphere of an inert gas with a low dew point is employed for process steps, whereby highly reliable light-emitting device where entry of impurities are prevented can be formed.

As the normal process apparatus A included in the cluster C1, a cleaning apparatus, a baking apparatus, and the like can be employed. For example, a spin cleaning apparatus, a batch-type cleaning apparatus, a hot plate-type or oven-type baking apparatus, and the like can be employed. The baking apparatus may be a vacuum baking apparatus.

Although the example of the cluster C1 illustrated in FIG. 6A includes two normal-pressure processing apparatuses A (normal-pressure processing apparatuses A1 and A2), three or more normal-pressure processing apparatuses A may be provided for an improvement in throughput.

### <Clusters C2, C5, C8, and C11>

FIG. 6B is a top view illustrating an apparatus structure applicable to the clusters C2, C5, C8, and C11. The clusters C2, C5, C8, and C11 are each a group of apparatuses mainly for forming an organic compound film and an inorganic film. The clusters C2, C5, C8, and C11 each include the buffer chamber B1 corresponding to a load chamber, the buffer chamber B2 corresponding to an unload chamber, the transfer chamber TF, and a plurality of vacuum processing apparatuses V. The transfer chamber TF is provided with the delivery device AM.

The buffer chamber B1, the buffer chamber B2, and the plurality of vacuum processing apparatuses V are connected to the transfer chamber TF through respective gate valves 20.

The delivery device AM can transfer the object to be processed from any one of the buffer chamber B1, the buffer chamber B2, and the plurality of vacuum processing apparatuses V to another of them.

When the manufacturing equipment is activated, the buffer chambers B1 and B2 are controlled under reduced pressure or normal pressure. Under the normal pressure control, an inert gas with a low dew point is preferably introduced. The transfer chamber TF and the plurality of vacuum processing apparatuses V are controlled under reduced pressure.

Each of the clusters C2, C5, C8, and C11 is connected to a vacuum pump VP (see FIG. 5), and the respective gate valves 20 are provided to connect the vacuum processing apparatuses V with the transfer chamber TF. Thus, different processes can be performed in parallel in the plurality of vacuum processing apparatuses V.

Note that the vacuum processing means processing in an environment controlled under reduced pressure. Thus, the vacuum processing includes processing for performing the pressure control under reduced pressure with introduction of a process gas, besides the processing in high vacuum.

As the vacuum apparatuses V included in the clusters C2, C5, C8, and C11, for example, film-formation apparatuses such as an evaporation apparatus, a sputtering apparatus, a CVD apparatus, and an ALD apparatus can be employed. Furthermore, a surface treatment apparatus may be included.

The surface treatment apparatus can have a structure same as that of the plasma treatment apparatus CN mentioned above and can perform a surface treatment step. The object to be processed may have a surface condition (e.g., wettability) varying depending on the previous step. In the case where the next step of the object to be processed is formation of the organic compound film, a defect such as peeling occurs in some cases unless the surface of the object to be proceed is in an appropriate condition. Thus, it is preferable that a surface treatment apparatus perform plasma treatment using a gas containing halogen to improve the surface condition of the object to be processed.

For example, in the case where the film-formation surface is an oxide, the surface of the oxide comes to have hydrophilicity in the previous step in some cases. In this case, a hydrophilic group in the film-formation surface is substituted by fluorine or a fluoroalkyl group by plasma treatment using a fluorine-based gas, whereby the surface can have a hydrophobic property, and a peeling defect can be prevented. As the fluorine-based gas, for example, fluorocarbon such as CF₄, C₂F₆, C₄F₆, C₄F₈, or CHF₃, SF₆, NF₃, or the like can be used. In addition, helium, argon, hydrogen, or the like may be added to the above gas.

Alternatively, a coating apparatus may be used as the surface treatment apparatus. For example, a method such as spin coating, dip coating, or spray coating, a method in which the object to be processed is exposed to an atmosphere of a coating agent, or the like can be used. As the coating agent, a silane coupling agent such as hexamethyldisilazane (HMDS) can be used for example, whereby a surface of the object to be processed can be made to have a hydrophobic property. Note that since the coating apparatus is used for a normal pressure processing, it is preferable that another cluster including a coating apparatus be provided separately.

As the CVD apparatus, a thermal CVD apparatus using heat, a plasma enhanced CVD (PECVD) apparatus using plasma, or the like can be used. As the ALD apparatus, a thermal ALD apparatus using heat, a plasma enhanced ALD (PEALD) apparatus using plasma-enhanced reactant, or the like can be used.

Although the example of the clusters C2, C5, C8, and C11 illustrated in FIG. 6B includes six vacuum processing apparatuses V (vacuum processing apparatuses V1 to V6), seven or more vacuum processing apparatuses may be included to improve the throughput or prevent contamination. Each of the clusters C2, C5, C8, and C11 may have a plurality of clusters.

Three out of the clusters C2, C5, C8, and C11 are each used for forming an organic compound film included in the light-emitting device, and the other one of the clusters is used for forming an organic compound film included in the light-receiving device. For example, the clusters C2, C5, and C8 are each used for forming an organic compound film included in the light-emitting device, and the cluster C11 is used for forming an organic compound film included in the light-receiving device.

### <Clusters C3, C6, C9, C12>

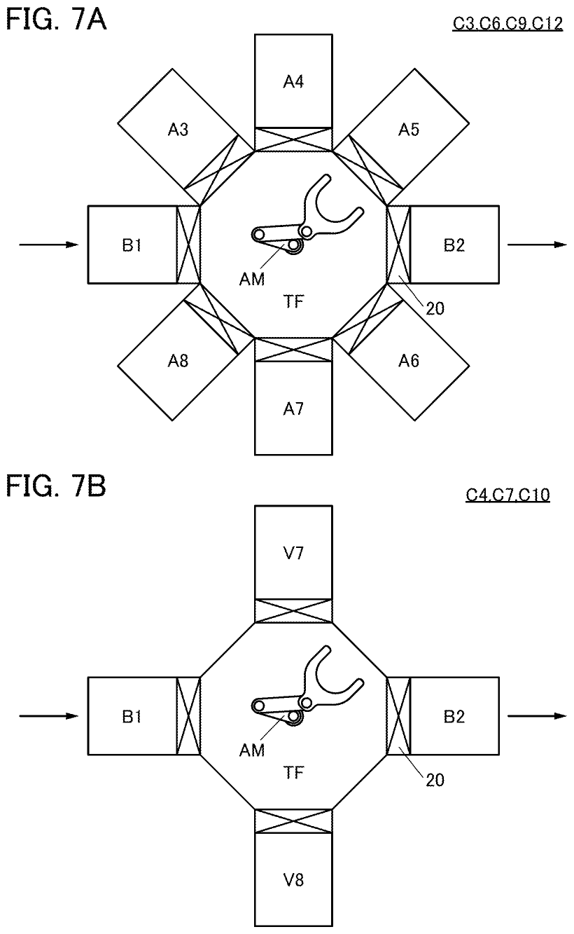

FIG. 7A is a top view illustrating an apparatus structure applicable to the clusters C3, C6, C9, and C12. The clusters C3, C6, C9, and C12 are each a group of apparatuses mainly for performing a lithography step. The C3, C6, C9, and C12 each include the buffer chamber B1 corresponding to a load chamber, the buffer chamber B2 corresponding an unload chamber, the transfer chamber TF, and the plurality of normal-pressure processing apparatuses A. The transfer chamber TF is provided with the delivery device AM.

The buffer chamber B1, the buffer chamber B2, and the plurality of normal-pressure processing apparatuses A are connected to the transfer chamber TF through respective gate valves 20.

The delivery device AM can transfer the object to be processed from any one of the buffer chamber B1, the buffer chamber B2, and the plurality of normal-pressure processing apparatuses A to another of them.

When the manufacturing equipment is activated, the buffer chambers B1 and B2 are controlled under reduced pressure or normal pressure. The transfer chamber TF and the plurality of normal-pressure processing apparatuses A are controlled under normal pressure. Under the normal pressure control, an inert gas with a low dew point is preferably introduced.

Each of the clusters C3, C6, C9, and C12 is connected to a valve through which an inert gas (IG) is introduced (see FIG. 5) and accordingly can be controlled in an inert gas atmosphere.

As the normal-pressure processing apparatuses A included in the clusters C3, C6, C9, and C12, apparatuses for performing a lithography step can be performed. For example, in the case where a photolithography step is performed, a resin (photoresist) coating apparatus, a light-exposure apparatus, a baking apparatus, and the like may be employed. In the case where a nanoimprint lithography step is performed, a resin coating apparatus using an UV curable resin or the like, a nanoimprint apparatus, and the like can be employed. In addition, depending on the usage, a cleaning apparatus, a wet etching apparatus, a coating apparatus, a resist peeling apparatus, and the like may be employed for the normal-pressure processing apparatuses A.

Although the example of the clusters C3, C6, C9, and C12 illustrated in FIG. 7A includes six normal-pressure processing apparatuses A (normal-pressure processing apparatuses A3 to A8), seven or more normal-pressure processing apparatuses A may be included to improve the throughput or prevent contamination. Each of the clusters C3, C6, C9, and C12 may have a plurality of clusters.

### <Clusters C4, C7, and C10>

FIG. 7B is a top view illustrating an apparatus structure applicable to the clusters C4, C7, and C10. The clusters C4, C7, and C10 are each a group of apparatuses mainly for etching the organic compound and removing a resist mask. The clusters C4, C7, and C10 each include the buffer chamber B1 corresponding to a load chamber, the transfer chamber TF, the buffer chamber B2 corresponding to an unload chamber, and the plurality of vacuum processing apparatuses V. The transfer chamber TF is provided with the delivery device AM.

The buffer chamber B1, the buffer chamber B2, and the plurality of vacuum processing apparatuses V are connected to the transfer chamber TF through respective gate valves 20.

The delivery device AM can transfer the object to be processed from any one of the buffer chamber B1, the buffer chamber B2, and the plurality of vacuum processing apparatuses V to another of them.

When the manufacturing equipment is activated, the buffer chambers B1 and B2 are controlled under the reduced pressure or normal pressure. Under the normal pressure control, an inert gas with a low dew point is preferably introduced. The transfer chamber TF and the plurality of vacuum processing apparatuses V are controlled under reduced pressure.

Each of the clusters C4, C7, and C10 is connected to a vacuum pump VP (see FIG. 5), and the respective gate valves 20 are provided to connect the vacuum processing apparatuses V with the transfer chamber TF. Thus, different processes can be performed in parallel in the plurality of vacuum processing apparatuses V.

As the vacuum processing apparatuses V included in the clusters C4, C7, and C10, a dry etching apparatus can be employed, for example. A dry etching apparatus having an ashing function may be employed. With the ashing function, a resist mask can be removed.

Although the example of the clusters C4, C7, and C10 illustrated in FIG. 7B includes two vacuum processing apparatuses V (vacuum processing apparatuses V7 and V8), three or more vacuum processing apparatuses V may be included in order to improve the throughput or prevent contamination.

### <Cluster C16>

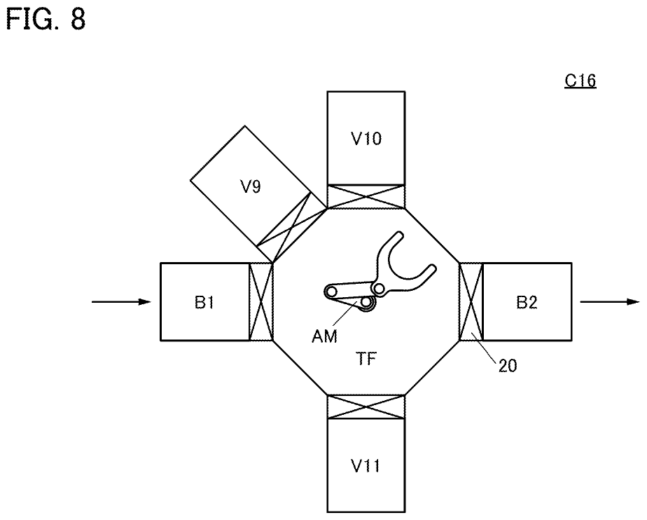

FIG. 8 is a top view illustrating an apparatus structure applicable to the cluster C16. The cluster C16 is a group of apparatuses mainly for performing film formation of an organic compound, a conductive film, and a protective film. The cluster C16 includes the buffer chamber B1 corresponding to a load chamber, the buffer chamber B2 corresponding to an unload chamber, the transfer chamber TF, and the plurality of vacuum processing apparatuses. The transfer chamber TF is provided with the delivery device AM.

The buffer chamber B1, the buffer chamber B2, and the plurality of vacuum processing apparatuses V are connected to the transfer chamber TF through respective gate valves 20.

The delivery device AM can transfer the object to be processed from any one of the buffer chamber B1, the buffer chamber B2, and the plurality of vacuum processing apparatuses V to another of them.

When the manufacturing equipment is activated, the buffer chamber B1 is controlled under reduced pressure. The buffer chamber B2 is controlled under reduced pressure or normal pressure. Under the normal pressure control, an inert gas with a low dew point is preferably introduced. The transfer chamber TF and the plurality of vacuum processing apparatuses V are controlled under reduced pressure.

The cluster C16 is connected to the vacuum pump VP (see FIG. 5), and the respective gate valves 20 are provided to connect the vacuum processing apparatuses V with the transfer chamber TF through. Thus, different processes can be performed in parallel in the plurality of vacuum processing apparatuses V.

As the vacuum apparatuses V included in the cluster C16, for example, film-formation apparatuses such as an evaporation apparatus, a sputtering apparatus, a CVD apparatus, and an ALD apparatus can be employed.

Although the example of the cluster C16 illustrated in FIG. 8 includes three vacuum processing apparatuses V (vacuum processing apparatuses V9 to V11), four or more vacuum processing apparatuses V may be included to improve the throughput or prevent contamination.

With use of the manufacturing equipment having any of the above structures, highly reliable light-emitting device and light-receiving device sealed with a protective film can be formed without being exposed to the air in the manufacturing process.

For example, after the object to be processed is cleaned with the cluster C1, a light-emitting device emitting a first color is formed with the clusters C2 to C4. Next, a light-emitting device emitting a second color is formed with the clusters C5 to C7. Next, a light-emitting device emitting a third color is formed with the clusters C8 to C10. Next, a light-receiving device and a protective layer (barrier film) are formed with the clusters C11 to C13. Next, an organic insulating layer is formed with the cluster C14. Next, unnecessary components are removed with the cluster C15. After that, with the cluster C16, steps up to forming a conductive film, a protective film, and the like can be continuously performed in apparatuses under reduced pressure or in a controlled atmosphere. Details of these steps are described later.

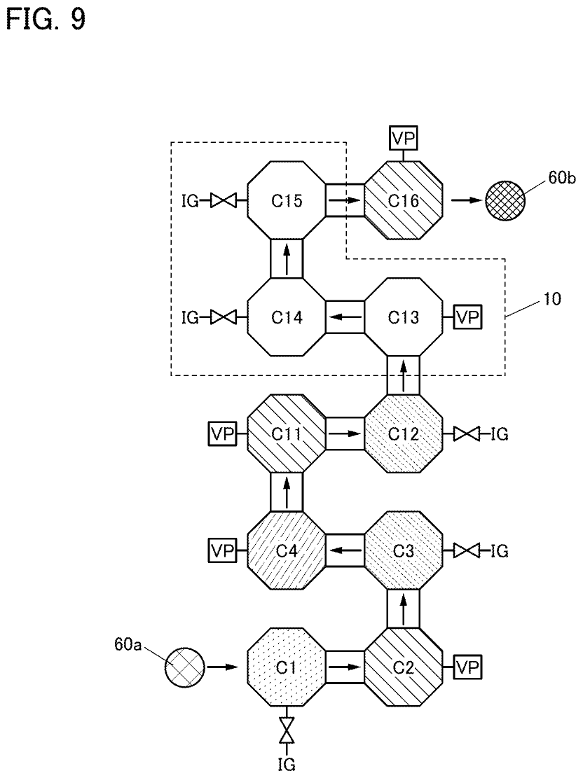

In the case where a light-emitting device emitting white light and light-emitting devices emitting the first to third colors with use of coloring layers such as color filters are formed, the manufacturing equipment has a structure such that the clusters C1, C2, C3, C4, C11, C12, C13, C14, C15, and C16 are sequentially connected as illustrated in FIG. 9, and an organic compound layer emitting white light may be formed with the clusters C2 to C4.

### Structure Example 3

Although Structure Examples 1 and 2 each show the example of manufacturing equipment with an in-line system where the clusters are connected through the buffer chambers, a structure in which each cluster independently includes a load chamber LD and an unload chamber ULD may be employed.

In such a structure, the object to be processed is preferably put and sealed in a container where an atmosphere is controlled so as not to be exposed to the air, and the container is moved between the clusters.

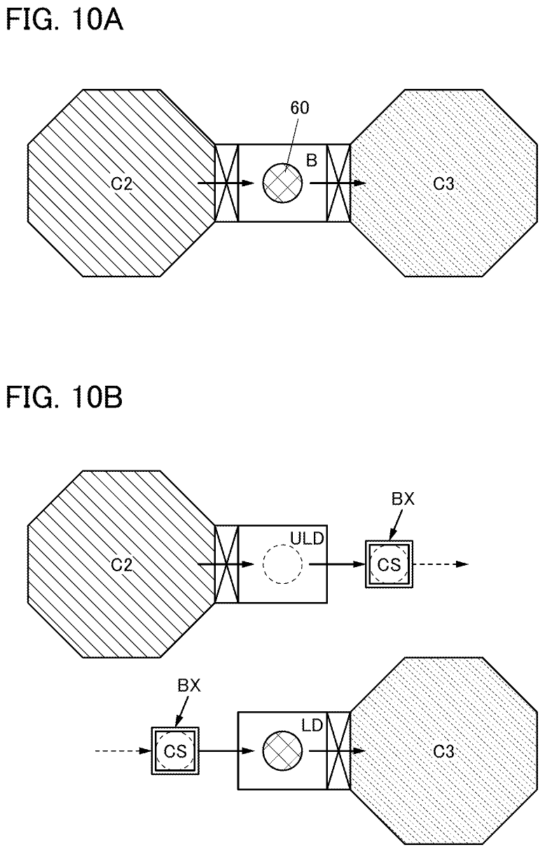

FIG. 10A is a schematic diagram of Structure Examples 1 and 2 and illustrates an example in which the cluster C2 is connected to the cluster C3 through a buffer chamber B. An object to be processed 60 is processed in the cluster C2 and then transferred to the cluster C3 through the buffer chamber B.

FIG. 10B is a schematic diagram of Structure Example 3 and illustrate an example where the load chamber LD and the unload chamber ULD are provided for each of the cluster C2 and the cluster C3. The object 60 to be processed is contained in a cassette CS in the unload chamber ULD of the cluster C2 and moved between the clusters in a state where the cassette CS containing the object is put into a delivery container BX whose atmosphere is controlled. Then, the cassette CS is transferred to the load chamber LD of the cluster C3. During this transfer, the cassette CS is put into the delivery container BX or the cluster without not being exposed to the air.

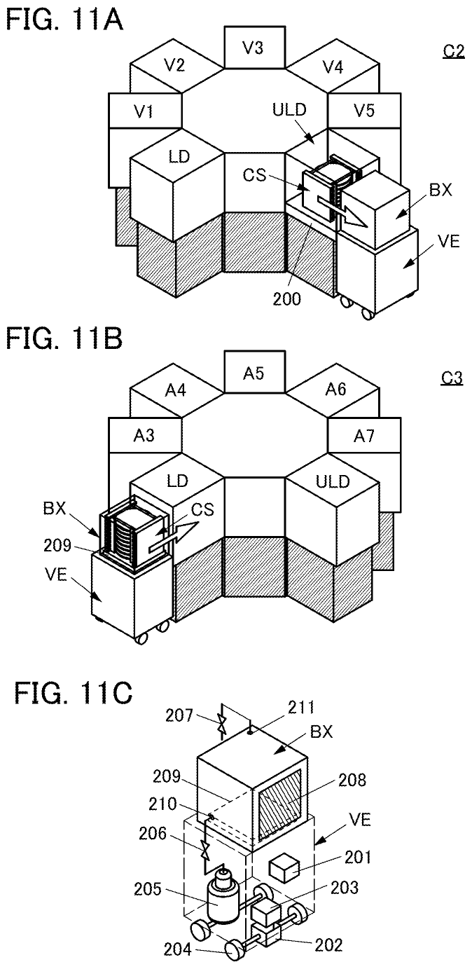

FIG. 11A illustrates the state of carrying out of the cassette CS from the cluster C2. Note that aiming for simplification, this diagram illustrates no gate valves and a transparent wall of the unload chamber ULD.

First, all objects to be processed are contained in the cassette CS placed in the unload chamber ULD, and in this state, the atmosphere of the unload chamber ULD is replaced with an inert gas atmosphere. In addition, the atmosphere inside the delivery container BX provided on a delivery vehicle VE is replaced with an inert gas atmosphere. At this time, it is preferable that the unload chamber ULD and the delivery container BX be set in a positive pressure state so that the atmospheric air does not flow therein. The structure preferable for the delivery container BX is such that the atmospheric air does not flow therein, and the delivery container BX may be evacuated to vacuum to be in a negative pressure.

Next, the carry-in port of the unload chamber ULD is docked to the carry-in/out port of the delivery container BX, whereby the cassette CS is transferred with a transfer device 200 from the unload chamber ULD to the delivery container BX. Then, the carry-in/out port of the delivery container BX is closed so that the inside of the delivery container BX is kept having the inert gas atmosphere, and in this state, the delivery container BX is transferred to the cluster C2 with the delivery vehicle VE.

FIG. 11B illustrates the state of carrying the cassette CS into the cluster C3. Note that aiming for simplification, this diagram illustrates a transparent wall of the delivery container BX.

First, the atmosphere in the load chamber LD is replaced with an inert gas atmosphere. Next, the carry-in port of the load chamber LD is docked to the carry-in/out port of the delivery container BX, whereby the cassette CS is transferred with a transfer device 209 from the delivery container BX to the load chamber LD. Then, the carry-in port of the load chamber LD is closed, and the processing in the cluster C2 starts.

FIG. 11C illustrates the delivery container BX and the delivery vehicle VE. The delivery vehicle VE includes a controller 201, a power source 202, a battery 203, a gas cylinder 205 filled with an inert gas, and the like. The power source 202 connects the battery 203 and wheels 204. The delivery vehicle VE can be moved manually or automatically with use of the controller 201.

The delivery container BX includes an inlet 210 and an outlet 211 for a gas, and the inlet 210 is connected to the gas cylinder 205 through a valve 206. The outlet 211 is connected to a valve 207. One or both of the valve 206 and the valve 207 is/are a conductance valve which enables the inside of the delivery container BX to be controlled to have a positive pressure with an inert gas. Nitrogen, argon, or the like is preferably used as the inert gas.

Furthermore, the delivery container BX includes a carry-in/out port 208 and the transfer device 209. There is no limitation on the form of the carry-in/out port 208; for example, a door, a shutter, or the like can be employed.

The transfer device 209 can transfer the cassette CS. Note that in the description of FIGS. 11A and 11B, the transfer device 200 provided for the unload chamber ULD is used to transfer the cassette to the delivery container BX, and the transfer device 209 provided for the delivery container BX is used to transfer the cassette to the load chamber LD. However, either the transfer device 200 or the transfer device 209 can be used for this operation. A structure where either the transfer device 200 or the transfer device 209 is omitted may be employed.

Although the above describes the clusters C2 and C3 as the examples, the independent cluster structure is applicable to the other clusters.

### <Vacuum Processing Apparatus V>

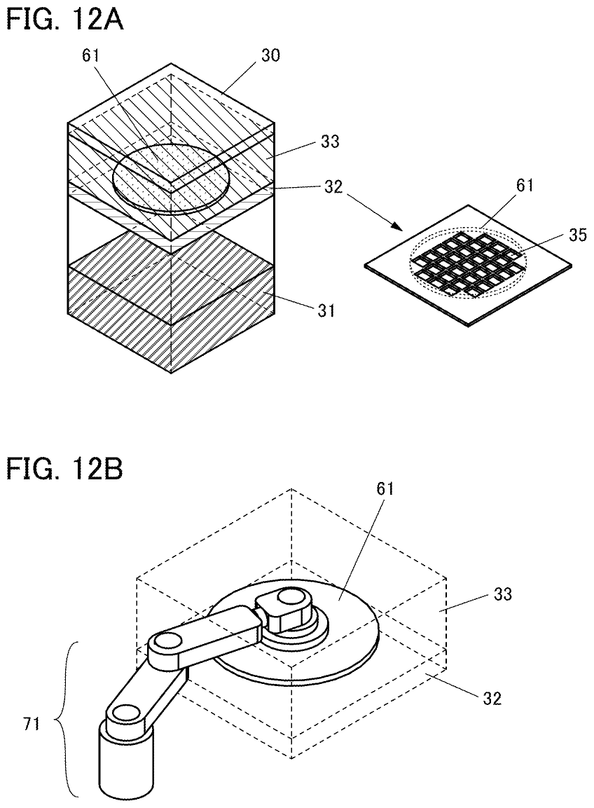

FIG. 12A illustrates a film-formation apparatus 30 in which a substrate (object to be processed) is placed in a face-down manner, as an example of the vacuum processing apparatus V. Note that aiming for simplification, this diagram illustrates a transparent chamber wall and no gate valve.

The film-formation apparatus 30 includes a film-formation material supply unit 31, a mask jig 32, and a substrate alignment unit 33. The film-formation material supply unit 31 is provided with an evaporation source when the film-formation apparatus 30 is an evaporation apparatus. Alternatively, the film-formation material supply unit 31 is provided with a target (cathode) when the film-formation apparatus 30 is a sputtering apparatus.

As illustrated in FIG. 12B, a substrate 61 in an inverted state can be carried in the substrate alignment unit 33 with a delivery device 71. The mask jig 32 is located below the substrate alignment unit 33. A circuit and the like are provided on the surface of the substrate 61 in advance, and the substrate 61 is attached closely to the mask jig 32 so as to avoid film formation in an unnecessary area. At this time, the substrate alignment unit 33 performs the position alignment between a portion of the substrate 61 where film formation is needed and an opening 35 of the mask jig 32.

Components such as a light-emitting device and a light-receiving device are formed in the opening 35; thus, the opening 35 is preferably adjusted in accordance with the purpose. For example, the size of the opening 35 can be determined depending on the size of an exposed region described below.

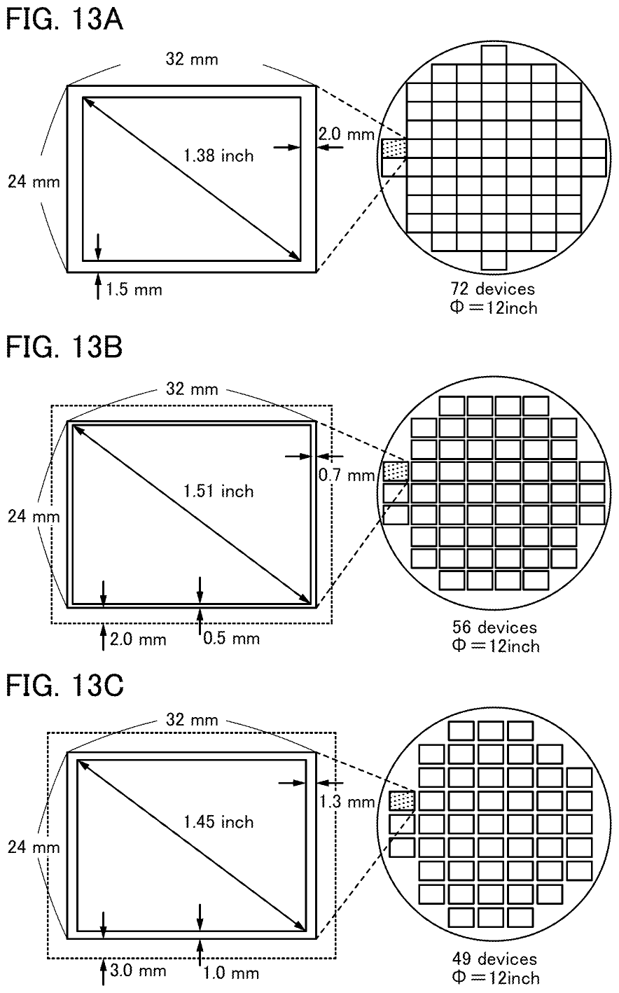

FIGS. 13A to 13C illustrate examples of the number of display devices taken out from one substrate (e.g., silicon wafer) with a diameter φ=12 inches. The number of the display devices taken out in FIGS. 13A to 13C is estimated, assuming that an external connection terminal is extracted from a rear surface with use of a through electrode. Thus, a display region can be set large. Note that a pad may be provided in the exposed region. In this case, the display region is reduced in size, but the manufacturing cost for the structure of extracting the external connection terminal can be reduced.

Each example illustrated in FIGS. 13A to 13C is a case where the aspect ratio of the display region is 4:3.

The example illustrated in FIG. 13A is that a sealing region is provided on an inner side of a region (32 mm×24 mm) exposed by the light-exposure apparatus. In the example of FIG. 13A, the width of the sealing region in the vertical direction is 1.5 mm and that in the horizontal direction is 2.0 mm. In this case, the display region has a size of 28 mm×21 mm (the aspect ratio is 4:3) and a diagonal size of approximately 1.38 inches. The number of display devices taken out from one substrate is 72. When the width of the sealing region in the vertical direction is 2.0 mm and that in the horizontal direction is 2.65 mm, the display region has a size of 26.7 mm×20 mm (the aspect ratio is 4:3) and a diagonal size of approximately 1.32 inches. Alternatively, when the width of the sealing region in the vertical direction is 3.0 mm and that in the horizontal direction is 4.0 mm, the display region has a size of 24 mm×18 mm (the aspect ratio is 4:3) and a diagonal size of approximately 1.18 inches. In each case, the number of display devices taken out from one substrate is 72.

The examples illustrated in FIGS. 13B and 13C are each that a sealing region is provided outside the region (32 mm×24 mm) exposed by the light-exposure apparatus. In this case, the region except a space for the sealing region is exposed to light. A marker region is provided inside the exposed region. The example in FIG. 13B is that the width of the marker region in the vertical direction is 0.5 mm and that in the horizontal direction is 0.7 mm, and the width of the sealing region is 2.0 mm. In this case, the display region has a diagonal size of approximately 1.51 inches. The number of display devices taken out from one substrate is 56. When the width of the marker region in the vertical direction is 1.0 mm and that in the horizontal direction is 1.3 mm, the display region has a diagonal size of approximately 1.45 inches. The example in FIG. 13C is that the width of the marker region in the vertical direction is 1.0 mm and that in the horizontal direction is 1.3 mm, and the width of the sealing region is 3.0 mm. In this case, the display region of the display device has a diagonal size of approximately 1.45 inches. The number of display devices taken out from one substrate is 49, which is lower approximately by 13% than that in FIG. 13B.

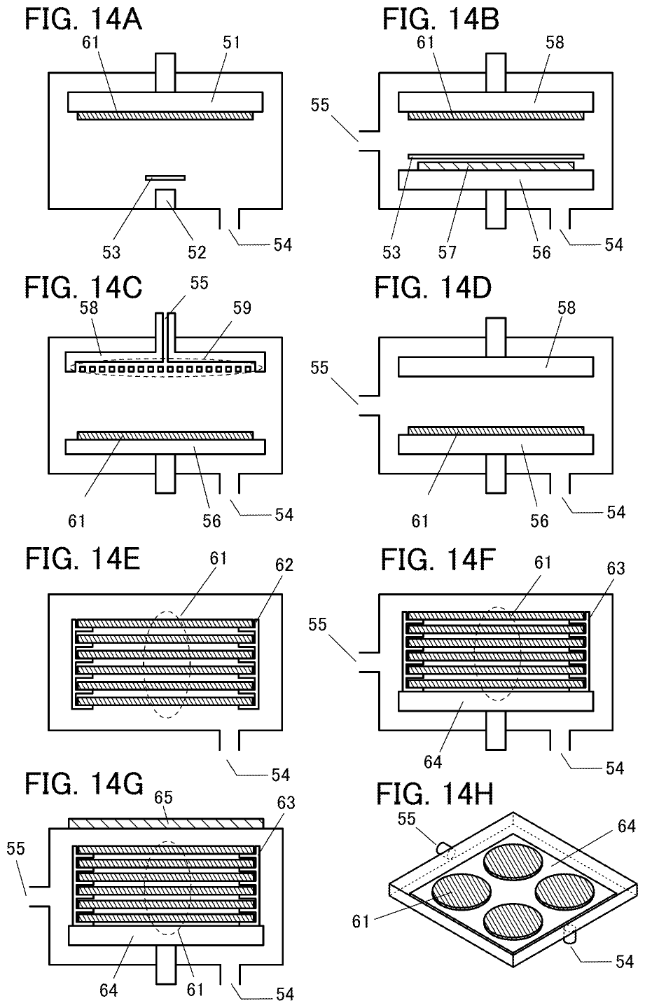

FIGS. 14A to 14F illustrate structure examples of a film-formation apparatus applicable to the vacuum processing apparatus V. FIG. 14A illustrates a vacuum evaporation apparatus which includes a substrate holder 51 for the substrate 61 that is an object to be processed, an evaporation source 52 such as a crucible, and a shutter 53. An outlet 54 is connected to a vacuum pump. The evaporation source is heated under reduced pressure to evaporate or sublimate a film-formation material. When the shutter is opened in this state, a film can be deposited.

FIG. 14B illustrates a sputtering apparatus which includes an upper electrode 58 provided with the substrate 61, a lower electrode 56 provided with a target 57, and the shutter 53. A gas inlet 55 is connected to a sputtering-gas supply source, and the outlet 54 is connected to a vacuum pump. For example, when DC power, RF power, or the like is applied between the upper electrode 58 and the lower electrode 56 under reduced pressure containing a noble gas or the like, a sputtering phenomenon occurs. When the shutter is opened in this state, a material of the target 57 can be deposited on the surface of the substrate 61.

FIG. 14C illustrates a plasma CVD apparatus which includes the upper electrode 58 provided with the gas inlet 55 and a shower plate 59, and the lower electrode 56 provided with the substrate 61. The gas inlet 55 is connected to a supply source of the raw material gas, and the outlet 54 is connected to a vacuum pump. When a raw-material gas is introduced under reduced pressure and a high-frequency power or the like is applied between the upper electrode 58 and the lower electrode 56, the raw-material gas is decomposed, and a target material can be deposited on the surface of the substrate 61.

FIG. 14D illustrates a dry etching apparatus which includes the upper electrode 58 and the lower electrode 56 provided with the substrate 61. The gas inlet 55 is connected to an etching-gas supply source, and the outlet 54 is connected to a vacuum pump. The etching gas is introduced under reduced pressure, and a high-frequency power or the like is applied between the upper electrode 58 and the lower electrode 56, whereby the etching gas is activated, and an inorganic film or an organic film formed over the substrate 61 can be etched. Furthermore, an ashing apparatus and a plasma treatment apparatus can have a structure similar to the above.

FIG. 14E illustrates a standby chamber which includes a substrate holder 62 storing a plurality of substrates 61. The outlet 54 is connected to a vacuum pump, and the substrate 61 is made to be in a standby state under reduced pressure. The number of the substrates 61 that can be stored in the substrate holder 62 may be determined as appropriate in consideration of the process time of previous and later steps.

FIG. 14F illustrates an ALD apparatus with a batch-type structure. The ALD apparatus includes a heater 64. The gas inlet 55 is connected to a supply source of a precursor or the like, and the outlet 54 is connected to a vacuum pump. A substrate holder 63 stores a plurality of substrates 61 and is located over the heater 64. The precursor and an oxidizer, or the like are alternately introduced from the gas inlet 55 under reduced pressure, whereby film deposition at an atomic layer level is repeated over the substrate 61. Note that when a single-wafer structure is used, the substrate holder 63 is not provided. A thermal CVD apparatus can have a structure similar to the above.

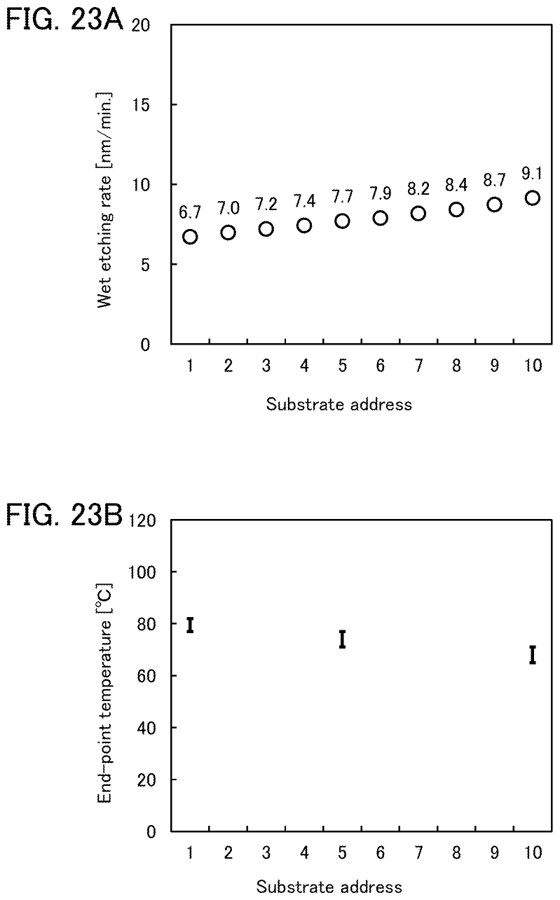

An example of film formation with an ALD apparatus is described. FIG. 23A is a graph showing a relation between the substrate address and the etching rate of AlOx films deposited (the deposition temperature set to 80° C.; the thickness set to 30 nm) with a batch-type ALD apparatus (illustrated in FIG. 14F). In the etching, a tetramethyl ammonium hydroxide (TMAH)-based etchant was used. As the substrate address, the lowest stage of a substrate cassette is set to 1, and the highest stage thereof is set to 10. FIG. 23B is a graph showing the relation between the substrate address and the end-point temperature of the substrate in the batch-type ALD apparatus.

According to FIG. 23A, the etching rate increases along with an increase in values of substrate address in the batch-type ALD apparatus. According to FIG. 23B, the end-point temperature of the substrate decreases along with an increase in values of the substrate address. In this manner, there is case where the etching rate and the end-point temperature of the substrate change depending on the substrate address in the batch-type ALD apparatus; thus, it is preferable to provide a mechanism that can adjust substrate temperatures in the height direction in the ALD apparatus. With such a mechanism, the ALD apparatus enables the substrate address dependence of film quality to be suppressed.

FIG. 14G illustrates an example in which a heater 65 is provided outside the upper portion of the film-formation chamber as a mechanism that can adjust substrate temperatures in the height direction. Examples of the heater 65 includes a silicon rubber heater and a jacket heater. Although the heater is provided outside the upper portion of the film-formation chamber in the example of FIG. 14G, the heater may be provided outside the side portion of the film-formation chamber.

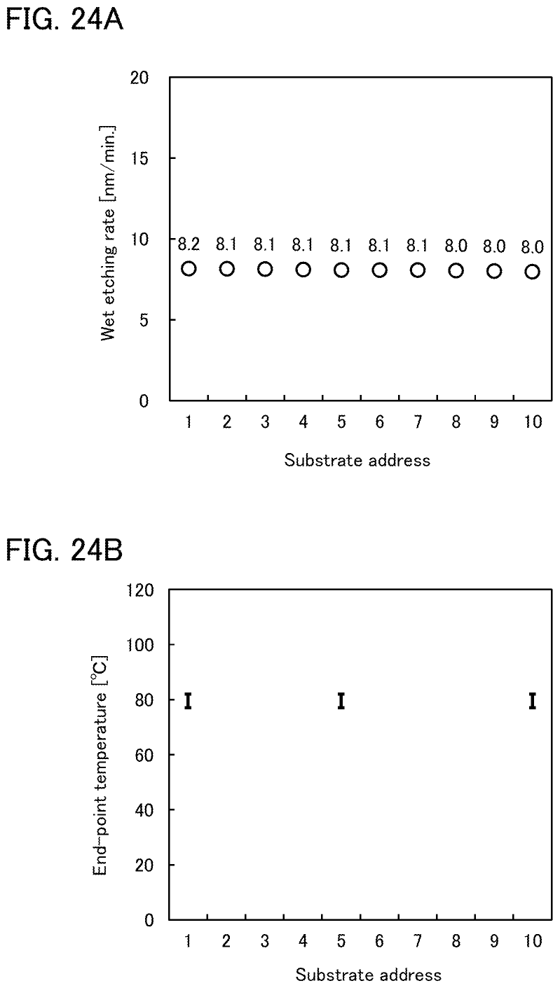

FIG. 24A is a graph showing the relation between the substrate address and the etching rate of AlOx films deposited with the ALD apparatus illustrated in FIG. 14G. FIG. 24B is a graph showing the relation between the substrate address and the end-point temperatures of the substrate. FIGS. 24A and 24B show comparison results of the etching rates and the end-point temperatures obtained in a manner similar to those for FIGS. 23A and 23B.

According to FIGS. 24A and 24B, providing the heater 65 enables an improvement of uniformity of the etching rate and the end-point temperature of the substrate in the height direction of the substrate address. In other words, providing the heater 65 enables the substrate address dependence of film quality to be eliminated.

FIG. 14H illustrates a batch-type ALD apparatus different from that in FIG. 14F. The structure is basically similar, but there is a difference in that the substrates 61 are arranged in a plane over the heater 64 and the substrate holder 63 is not used. It is acceptable that the gas inlet 55 be provided directly over the substrates 61, the heater 64 have a rotation mechanism or the like, and the substrates 61 pass directly below the gas inlet 55. With the rotation mechanism of the heater 64, the substrates 61 are shifted, which enables processing of a plurality of substrates.

Although four substrates 61 are set over the heater 64 in FIG. 14H, the number of substrates over the heater 64 may be two or one. In addition, the batch structure where the substrates 61 are arranged in a plane as illustrated in FIG. 14H may be employed for the apparatuses illustrated in FIGS. 14A to 14D.

This embodiment can be implemented in an appropriate combination with any of the structures described in the other embodiment.

### Embodiment 2

In this embodiment, specific examples of an organic EL element and a light-receiving element, which can be manufactured with equipment for manufacturing a light-emitting device and a light-receiving device of one embodiment of the present invention, will be described.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure.

In this specification and the like, a structure in which light-emitting layers in light-emitting devices of different colors (here, blue (B), green (G), and red (R)) are separately formed or separately patterned may be referred to as a side-by-side (SBS) structure. In this specification and the like, a light-emitting device capable of emitting white light may be referred to as a white light-emitting device. Note that a combination of white light-emitting devices with coloring layers (e.g., color filters) enables a full-color display device.

Structures of light-emitting devices can be classified roughly into a single structure and a tandem structure. A light-emitting device with a single structure includes one light-emitting unit between a pair of electrodes, and the light-emitting unit preferably includes one or more light-emitting layers. To obtain white light emission by using two light-emitting layers, the two light-emitting layers are selected such that emission colors of the light-emitting layers are complementary colors. For example, when emission colors of a first light-emitting layer and a second light-emitting layer are complementary colors, a light-emitting device can be configured to emit white light as a whole. To obtain white light emission by using three or more light-emitting layers, the light-emitting device is configured to emit white light as a whole by combining emission colors of the three or more light-emitting layers.

A light-emitting device having a tandem structure includes two or more light-emitting units between a pair of electrode, and each light-emitting unit preferably includes one or more light-emitting layers. To obtain white light emission, the structure is made so that light from light-emitting layers of the light-emitting units can be combined to be white light. Note that a structure for obtaining white light emission is similar to that in the case of a single structure. In a light-emitting device having a tandem structure, an intermediate layer such as a charge-generation layer is preferably provided between a plurality of light-emitting units.

When the white-light-emitting device (having a single structure or a tandem structure) and a light-emitting device having an SBS structure are compared to each other, the latter can have lower power consumption than the former. To reduce power consumption, a light-emitting device having an SBS structure is preferably used. Meanwhile, the white light-emitting device is preferable in terms of lower manufacturing cost or higher manufacturing yield because the manufacturing process of the white light-emitting device is simpler than that of a light-emitting device having an SBS structure.

The device with a tandem structure may include light-emitting layers emitting the same color (e.g., BB, GG, RR, and the like). The tandem structure emitting light from a plurality of layers requires high voltage for light emission but reduces the amount of current necessary for obtaining emission intensity at the same level as that from the single structure. Thus, with the tandem structure, current stress on each light-emitting unit can be reduced and the element lifetime can be extended.

The display device of one embodiment of the present invention includes a light-emitting device and a light-receiving device. For example, three kinds of light-emitting devices emitting red (R), green (G), and blue (B) light are included, whereby a full-color display device can be obtained.

The display device is fabricated by processing an EL layer (an organic layer contributing to light emission of the light-emitting device) and a photoelectric conversion layer (an organic layer contributing to photoelectric conversion of the light-receiving device) into fine patterns by a photolithography method without using a shadow mask such as a metal mask. With the patterning process, a high-resolution display device with a high aperture ratio, which has been difficult to achieve, can be fabricated. Moreover, EL layers can be formed separately, enabling the display device to perform extremely clear display with high contrast and high display quality.

It is difficult to set the distance between EL layers for different colors or between an EL layer and a photoelectric conversion layer to be less than 10 μm with a formation method using a metal mask, for example. In contrast, with use of the above method, the distance can be decreased to be less than or equal to 3 μm, less than or equal to 2 μm, or less than or equal to 1 μm. For example, with use of an exposure tool for LSI, the distance can be decreased to be less than or equal to 500 nm, less than or equal to 200 nm, less than or equal to 100 nm, or less than or equal to 50 nm. Accordingly, the area of a non-light-emitting region that may exist between two light-emitting devices or between the light-emitting device and the light-receiving device can be significantly reduced, and the aperture ratio can be close to 100%. For example, the aperture ratio lower than 100% but higher than or equal to 50%, higher than or equal to 60%, higher than or equal to 70%, higher than or equal to 80%, or higher than or equal to 90% can be achieved.

Furthermore, patterns of the EL layer and the photoelectric conversion layer themselves can be made extremely smaller than that in the case of using a metal mask. For example, in the case of using a metal mask for forming EL layers separately, a variation in the thickness of the pattern occurs between the center and the edge of the pattern. This causes a reduction in an effective area that can be used as a light-emitting region with respect to the entire pattern area. In contrast, in the manufacturing method of one embodiment of the present invention, a pattern is formed by processing a film deposited to have a uniform thickness, which enables a uniform thickness in the pattern. Thus, even with a fine pattern, almost the entire area can be used as a light-emitting region. Therefore, the above method makes it possible to obtain a high resolution display apparatus with a high aperture ratio.

In many cases, an organic film formed using a fine metal mask (FMM) has an extremely small taper angle (e.g., a taper angle greater than 0° and less than 30°) so that the thickness of the film becomes smaller in a portion closer to an end portion. Therefore, it is difficult to clearly observe a side surface of an organic film formed using an FMM because the side surface and a top surface are continuously connected. In contrast, an EL layer included in one embodiment of the present invention is processed without using an FMM, and has a clear side surface. In particular, part of the taper angle of the EL layer included in one embodiment of the present invention is preferably greater than or equal to 30° and less than or equal to 120°, further preferably greater than or equal to 600 and less than or equal to 120°.

Note that in this specification and the like, an end portion of an object having a tapered shape indicates that the end portion of the object has a cross-sectional shape in which the angle between a side surface (a top surface) of the object and a surface on which the object is formed (a bottom surface) is greater than 0° and less than 900 in a region of the end portion, and the thickness continuously increases from the end portion. A taper angle refers to an angle between a bottom surface (a surface on which an object is formed) and a side surface (a top surface) at an end portion of the object.

### Structure Example

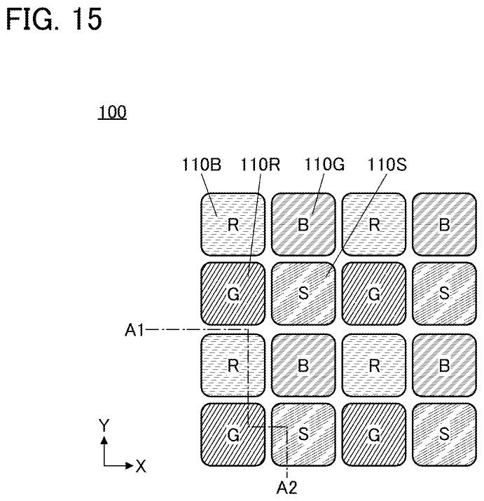

FIG. 15 is a schematic top view of a display device 100 fabricated using equipment for manufacturing a light-emitting device and a light-receiving device. The display device 100 includes a plurality of light-emitting devices 110R that emit red light, a plurality of light-emitting devices 110G that emit green light, a plurality of light-emitting devices 110B that emit blue light, and a plurality of light-receiving devices 110S. In FIG. 15, regions of the light-emitting devices and the light-receiving device are denoted by R, G, B, and S to easily differentiate the light-emitting devices and the light-receiving device.

The light-emitting devices 110R, the light-emitting devices 110G, the light-emitting devices 110B, and the light-receiving devices 110S are arranged in a matrix. FIG. 15 illustrates a structure in which two types of elements are alternately arranged in one line. Note that the arrangement method of the light-emitting devices and the light-receiving device is not limited thereto; another method such as a stripe, S stripe, delta, Bayer, zigzag, PenTile, or diamond arrangement may also be used.

As each of the light-emitting devices 110R, 110G, and 110B, an EL element such as an organic light-emitting diode (OLED) or a quantum-dot light-emitting diode (QLED) is preferably used. As a light-emitting substance included in the EL element, a substance emitting fluorescence (a fluorescent material), a substance emitting phosphorescence (a phosphorescent material), an inorganic compound (e.g., a quantum dot material), a substance exhibiting thermally activated delayed fluorescence (a thermally activated delayed fluorescent (TADF) material), or the like can be used.

As the light-receiving device 110S, an organic photodiode can be used. The photoelectric conversion layer included in the organic photodiode is preferably formed by co-evaporation of an n-type semiconductor and a p-type semiconductor. Alternatively, the photoelectric conversion layer may be formed by stacking an n-type semiconductor and a p-type semiconductor.

In addition to the photoelectric conversion layer, the light-receiving device may further include a layer containing a substance with a high hole-transport property, a substance with a high electron-transport property, or a substance with a bipolar property (a substance with a high electron- and hole-transport property). Without limitation to the above, the light-receiving device may further include a substance with a high hole-injection property, a hole-blocking material, a material with a high electron-injection property, an electron-blocking material, and the like.

Either a low molecular compound or a high molecular compound can be used for the light-emitting devices and the light-receiving device, and an inorganic compound may also be included. Each of the layers included in the light-emitting devices and the light-receiving device can be formed by any of the following methods: an evaporation method (including a vacuum evaporation method), a transfer method, a printing method, an inkjet method, a coating method, and the like.

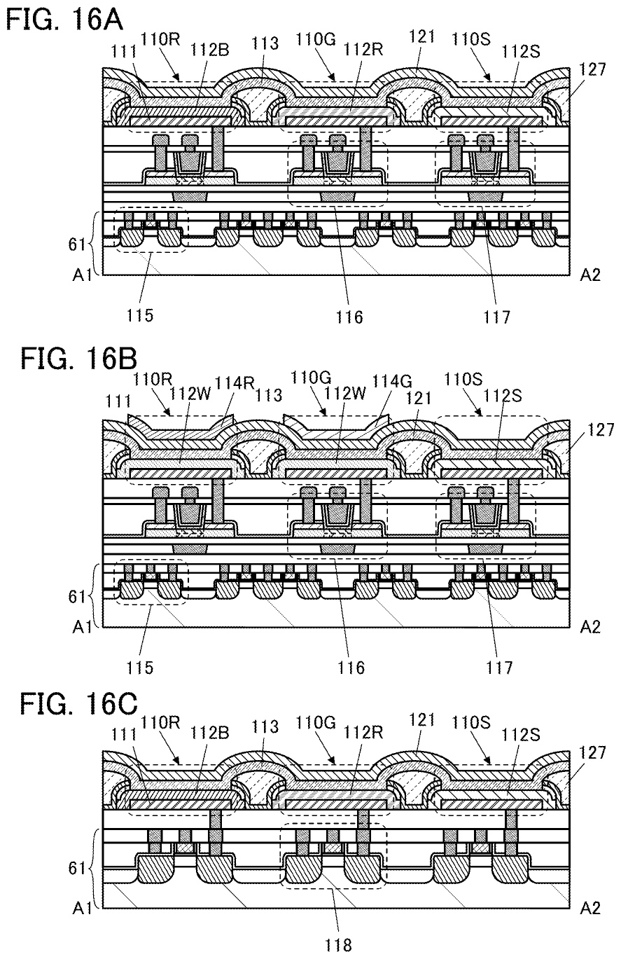

FIG. 16A is a schematic cross-sectional view along the dashed-dotted line A1-A2 in FIG. 15.

FIG. 16A shows cross sections of the light-emitting device 110R, the light-emitting device 110G, and the light-receiving device 110S. Although the light-emitting device 110B is not illustrated, for its basic structure, description of the light-emitting device 110R and the light-emitting device 110G can be referred to.

The light-emitting device 110R, the light-emitting device 110G, and the light-receiving device 110S are provided over a pixel circuit and includes a pixel electrode 111 and a common electrode 113.

The light-emitting device 110R includes an EL layer 112R between the pixel electrode 111 and the common electrode 113. The EL layer 112R contains a light-emitting organic compound that emits light with a peak at least in a red wavelength range. An EL layer 112G included in the light-emitting device 110G contains a light-emitting organic compound that emits light with a peak at least in a green wavelength range. An organic layer 112S included in the light-receiving device 110S contains an organic compound having sensitivity to visible light or infrared light.

The EL layers 112R and 112G may each include one or more of an electron-injection layer, an electron-transport layer, a hole-injection layer, and a hole-transport layer in addition to a layer containing a light-emitting organic compound (the light-emitting layer). The organic layer 112S may include at least one of an electron-injection layer, an electron-transport layer, a hole-injection layer, and a hole-transport layer in addition to a layer containing an organic compound having a photoelectric conversion property (the photoelectric conversion layer).

The pixel electrode 111 is provided in each of the light-emitting device and the light-receiving device. The common electrode 113 is provided as one continuous layer shared by the light-emitting device and the light-receiving device. A conductive film that transmits visible light is used for one of the pixel electrode 111 and the common electrode 113, a reflective conductive film is used for the other. When the pixel electrode 111 is a light-transmitting electrode and the common electrode 113 is a reflective electrode, a bottom-emission display device is obtained. When the pixel electrode 111 is a reflective electrode and the common electrode 113 is a light-transmitting electrode, a top-emission display device is obtained. Note that when both the pixel electrode 111 and the common electrode 113 transmit light, a dual-emission display device can be obtained. In this embodiment, an example of manufacturing a top-emission display device having a top-emission structure is described.

The EL layer 112R, the EL layer 112G, and the organic layer 112S each include a region in contact with a top surface of the pixel electrode 111.

As illustrated in FIG. 16A, spaces are provided between the two EL layers of the light-emitting devices and between the EL layer and the organic layer of the light-emitting device and the light-receiving device. In this manner, the EL layer 112R, the EL layer 112G, and the organic layer 112S are preferably provided so as not to be in contact with each other. This effectively prevents unintentional light emission from being caused by current flowing through two adjacent EL layers. As a result, the contrast can be increased to achieve a display device with high display quality. Furthermore, leakage current between the EL layer and the organic layer can be inhibited, and noise of the light-receiving device can be suppressed.

A protective layer 121 is provided over the common electrode 113 so as to cover the light-emitting devices 110R and 110G and the light-receiving device 110S. The protective layer 121 has a function of preventing diffusion of impurities into the light-emitting devices and the light-receiving device from the above. Alternatively, the protective layer 121 has a function of trapping (also called gettering) impurities (such as water and hydrogen typically) that may enter the light-emitting device and the light-receiving device.

The protective layer 121 can have, for example, a single-layer structure or a stacked-layer structure at least including an inorganic insulating film. Examples of the inorganic insulating film include an oxide film and a nitride film such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as indium gallium oxide or indium gallium zinc oxide may be used for the protective layer 121.

The pixel electrode 111 is electrically connected to one of a source and a drain of the transistor 116 or the transistor 117. A transistor containing a metal oxide in a channel formation region (hereinafter also referred to as OS transistor) can be used, for example, as the transistors 116 and 117. The OS transistor has higher mobility than a transistor using amorphous silicon and has excellent electrical characteristics. In addition, crystallization needed in the manufacturing process using polycrystalline silicon is not necessary, and the OS transistor can be fabricated in the back end of line or the like. Therefore, the OS transistor can be formed over a transistor 115 using silicon in a channel formation region formed with the substrate 61 (hereinafter, such a transistor is referred to as Si transistor) without a bonding step.

The transistor 116 is included in a pixel circuit including the light-emitting devices. The transistor 117 is included in a pixel circuit including the light-receiving device. The transistor 115 is included in a driver circuit for the pixel circuit or the like. In other words, the pixel circuit can be formed over the driver circuit, which enables formation of a display device with a narrow frame.

As a semiconductor material used for an OS transistor, a metal oxide whose energy gap is greater than or equal to 2 eV, preferably greater than or equal to 2.5 eV, further preferably greater than or equal to 3 eV can be used.

In the OS transistor, the semiconductor layer has a large energy gap, and thus the OS transistor has an extremely low off-state current of several yA/μm (current per micrometer of a channel width). The off-state current per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current per micrometer of channel width of a Si transistor at room temperature is higher than or equal to 1 fA (1×10⁻¹⁵ A) and lower than or equal to 1 pA (1×10⁻¹² A). In other words, the off-state current of the OS transistor is lower than that of the Si transistor by approximately ten orders of magnitude.

An OS transistor has the following feature different from that of a Si transistor; impact ionization, an avalanche breakdown, a short-channel effect, or the like does not occur. Thus, the use of an OS transistor enables formation of a circuit having high withstand voltage and high reliability. Moreover, variations in electrical characteristics due to crystallinity unevenness, which are caused in Si transistors, are less likely to occur in OS transistors.

A semiconductor layer in an OS transistor can be, for example, a film represented by an In-M-Zn-based oxide that contains indium, zinc, and M (one or more metals selected from aluminum, titanium, gallium, germanium, yttrium, zirconium, lanthanum, cerium, tin, neodymium, and hafnium). The In-M-Zn-based oxide can be typically formed by a sputtering method. Alternatively, it may be formed using an ALD method.

For example, an oxide containing indium (In), gallium (Ga), and zinc (Zn) can be used as the In-M-Zn-based oxide. Alternatively, an oxide containing indium (In), aluminum (Al), and zinc (Zn) (also referred to as IAZO) may be used. Further alternatively, an oxide containing indium (In), aluminum (Al), gallium (Ga), and zinc (Zn) (also referred to as IAGZO) may be used.

It is preferable that the atomic ratio of metal elements of a sputtering target used for forming the In-M-Zn-based oxide by a sputtering method satisfy In≥M and Zn≥M. The atomic ratio between metal elements in such a sputtering target is preferably, for example, In:M:Zn=1:1:1, In:M:Zn=1:1:1.2, In:M:Zn=1:3:2, In:M:Zn=3:1:2, In:M:Zn=4:2:3, In:M:Zn=4:2:4.1, In:M:Zn=5:1:6, In:M:Zn=5:1:7, In:M:Zn=5:1:8, or close thereto. Note that the atomic ratio between metal elements in the formed semiconductor layer may vary from the above atomic ratio between metal elements in the sputtering target in a range of ±40%.

An oxide semiconductor with low carrier density is used for the semiconductor layer. For example, the semiconductor layer may use an oxide semiconductor whose carrier density is lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³, even further preferably lower than 1×10¹⁰/cm³, and higher than or equal to 1×10⁻⁹/cm³. Such an oxide semiconductor is referred to as a highly purified intrinsic or substantially highly purified intrinsic oxide semiconductor. The oxide semiconductor has a low density of defect states and can thus be regarded as having stable characteristics.

Note that, examples of a material for the semiconductor layer are not limited to those described above, and a material with an appropriate composition may be used in accordance with required semiconductor characteristics and electrical characteristics (e.g., field-effect mobility and threshold voltage) of the transistor. To obtain the required semiconductor characteristics of the transistor, it is preferable that the carrier density, the impurity concentration, the defect density, the atomic ratio between a metal element and oxygen, the interatomic distance, the density, and the like of the semiconductor layer be set to appropriate values.

Note that the display device illustrated in FIG. 16A includes an OS transistor and a light-emitting device having a metal maskless (MML) structure. With this structure, the leakage current that might flow through the transistor and the leakage current that might flow between adjacent light-emitting devices (also referred to as a lateral leakage current, a side leakage current, or the like) can become extremely low. In addition, when an image is displayed on the display device having this structure, the user can notice one or more of crispness, sharpness, and a high contrast ratio of an image. Note that when the leakage current that might flow through a transistor and the side leakage current between light-emitting elements are extremely low, light leakage or the like that might occur in black display can be reduced as much as possible (such display is also referred to as completely black display).

Although FIG. 16A illustrates the example in which the light-emitting device 110R and the light-emitting device 110G have different light-emitting layers, the present invention is not limited thereto. For example, as illustrated in FIG. 16B, the light-emitting devices 110R and 110G may include an EL layer 112W which emits white light and coloring layers 114R (red) and 114G (green) which overlap with the EL layer 112W, thereby emitting different colors. Note that the light-emitting device 110B not illustrated also includes the EL layer 112W, and a blue coloring layer is provided over the EL layer 112W.

The EL layer 112W can have a tandem structure in which EL layers emitting red, green, and blue light are connected in series, for example. Alternatively, an element in which light-emitting layers emitting red, green, and blue light are connected in series may be used. Instead of the EL layers or light-emitting layers emitting red and green light, an EL layer or light-emitting layer emitting yellow light can be used.

As illustrated in FIG. 16C, a pixel circuit may be formed with Si transistors (transistors 118) provided for the substrate 61, and one of a source and a drain of each transistor 118 may be electrically connected to the pixel electrode 111.

### <Example of Manufacturing Method>

An example of a manufacturing method of a light-emitting device and a light-receiving device with manufacturing equipment of the present invention, will be described below. Here, the light-emitting device and the light-receiving device included in the display device 100 described above are used an example for the description.

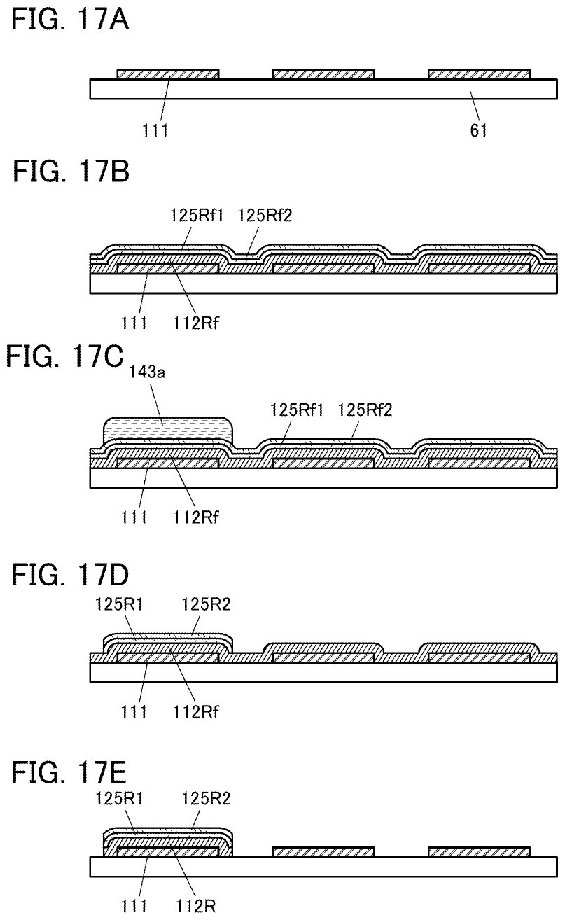

FIGS. 17A to 17E, FIGS. 18A to 18E, FIGS. 19A to 19E, and FIGS. 20A to 20E are schematic cross-sectional views illustrating steps in a method for manufacturing the light-emitting devices 110R and 110G and the light-receiving device 110S, described below. Although the description for the light-emitting device 110B is omitted, a manufacturing method similar to those of the light-emitting devices 110R and 110G, except for formation of an EL layer emitting blue light, can be used. The transistor 116 that is a component of the pixel circuit and the transistor 115 that is a component of the driver circuit, which are illustrated in FIG. 16A, are omitted in FIGS. 17A to 17E, FIGS. 18A to 18E, FIGS. 19A to 19E, and FIGS. 20A to 20E.

Note that thin films that constitute the display device (insulating films, semiconductor films, conductive films, and the like) can be formed by a sputtering method, a chemical vapor deposition (CVD) method, a vacuum evaporation method, an atomic layer deposition (ALD) method, or the like. Examples of the CVD method include a plasma-enhanced chemical vapor deposition (PECVD) method and a thermal CVD method. An example of a thermal CVD method is a metal organic CVD (MOCVD) method. The manufacturing equipment of one embodiment of the present invention can include an apparatus for forming thin films by the above method.

Furthermore, for formation of thin films included in the display device (e.g., insulating films, semiconductor films, and conductive films) and coating of a resin or the like used in a lithography step, the following method can be used: spin coating, dipping, spray coating, ink-jetting, dispensing, screen printing, offset printing, doctor blade coating, slit coating, roll coating, curtain coating, or knife coating. The manufacturing equipment of one embodiment of the present invention can include an apparatus for forming thin films by the above method. In addition, the manufacturing equipment of one embodiment of the present invention can include an apparatus for applying a resin by the above method.

Thin films included in the display device can be processed by a photolithography method or the like. Alternatively, the thin films may be processed by a nanoimprinting method. Alternatively, island-shaped thin films may be formed directly by a film formation method using a blocking mask.

There are two typical methods as a thin film processing method using a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used. It is preferable to use EUV, X-rays, or an electron beam because extremely minute processing can be performed. Note that a photomask is not needed when exposure is performed by scanning with a beam such as an electron beam.

For the etching of the thin films, dry etching, wet etching, or the like can be used. The manufacturing equipment of one embodiment of the present invention can include an apparatus for processing thin films by the above method.

### <Preparation for Substrate 61>

As the substrate 61, a substrate that has heat resistance high enough to withstand at least heat treatment performed later can be used. When an insulating substrate is used as the substrate 61, a glass substrate, a quartz substrate, a sapphire substrate, a ceramic substrate, an organic resin substrate, or the like can be used. Alternatively, a semiconductor substrate can be used. For example, a single crystal semiconductor substrate or a polycrystalline semiconductor substrate of silicon, silicon carbide, or the like; a compound semiconductor substrate of silicon germanium or the like; an SOI substrate; or the like can be used. Note that the shape of the substrate is not limited to a circular wafer, and a square substrate can also be used.

As the substrate 61, it is particularly preferable to use the above-described semiconductor substrate or insulating substrate where a semiconductor circuit including a semiconductor element such as a Si transistor is formed. The semiconductor circuit preferably forms a pixel circuit, a gate line driver circuit (a gate driver), a source line driver circuit (a source driver), or the like. In addition to the above, an arithmetic circuit, a memory circuit, or the like may be formed.

### <Formation of Pixel Circuit and Pixel Electrode 111>

Next, a plurality of pixel circuits are formed over the substrate 61, and the pixel electrode 111 is formed for each of the pixel circuits (see FIG. 17A). First, a conductive film to be the pixel electrode 111 is formed, a resist mask is formed by a photolithography method, and an unnecessary portion of the conductive film is removed by etching. Then, the resist mask is removed, whereby the pixel electrode 111 can be formed.

As the pixel electrode 111, it is preferable to use a material (e.g., silver or aluminum) having reflectance as high as possible in the whole wavelength range of visible light. The pixel electrode 111 formed using the material can be referred to as an electrode having a reflective property. This can increase both outcoupling efficiency and color reproducibility of the light-emitting devices. Furthermore, the conversion efficiency of the light-receiving device can be improved.

The light-emitting device preferably employs a microcavity structure. Therefore, one of pair of electrodes in the light-emitting device is preferably an electrode having properties of transmitting and reflecting visible light (a transflective electrode), and the other is preferably an electrode having a property of reflecting visible light (a reflective electrode). When the light-emitting device has a microcavity structure, light obtained from the light-emitting layer can be resonated between the electrodes, whereby light emitted from the light-emitting device can be intensified. For that reason, the pixel electrode 111 may have a stacked-layer structure of the material with high reflectivity and a light-transmitting conductive film (using indium tin oxide or the like).

Next, a baking step for removing moisture remaining on the surface of the pixel electrode 111 is performed. A vacuum baking apparatus or a film-formation apparatus can be used for the baking step. The vacuum baking is preferably performed at 100° C. or higher.

Next, the pixel electrode 111 is subjected to surface treatment. For example, the surface of the pixel electrode 111 is irradiated with plasma generated using a fluorine-based gas such as CF₄ with a plasma treatment apparatus. By the plasma treatment, the adhesion between the pixel electrode 111 and an organic compound film which is formed in the later step can be increased, which can suppress the occurrence of peeling defects.

### <Formation of EL Film 112Rf>

Next, an EL film 112Rf is formed over the pixel electrode 111. The EL film 112Rf is processed, whereby the EL layer 112R that is a component of the light-emitting device 110R can be formed.

The EL film 112Rf includes at least an organic compound film emitting red light. A structure may be employed in which at least one of films functioning as an electron-injection layer, an electron-transport layer, a charge-generation layer, a hole-transport layer, and a hole-injection layer is stacked in addition to the above. The EL film 112Rf can be formed by an evaporation method, a sputtering method, or an inkjet method, for example. Without limitation to this, the above-described film-formation method can be used as appropriate.

<Formation of protective films 125Rf1 and 125Rf2>

Next, a protective film 125Rf1 and a protective film 125Rf2 that are to be a protective layer 125R1 and a protective layer 125R2 are formed over the EL film 112Rf (see FIG. 17B).

The protective layer 125R1 and the protective layer 125R2 are tentative protective layers, which are also called mask layers, used for processing of the EL layer 112R and preventing the EL layer 112R from being degraded in a manufacturing process of light-emitting devices. The protective films 125Rf1 and 125Rf2 are preferably formed by a film-formation method that has high barrier property against moisture or the like and is less likely to give damage to an organic compound during film formation. Furthermore, the protective films 125Rf1 and 125Rf2 are preferably formed using a material for which an etchant less likely to give damage to the organic compound in an etching step is acceptable. For the protective films 125Rf1 and 125Rf2, an inorganic film such as a metal film, an alloy film, a metal oxide film, a semiconductor film, or an inorganic insulating film can be used.

For example, the protective films 125Rf1 and 125Rf2 are preferably formed using a metal such as tungsten, an inorganic insulating film such as an aluminum oxide film, or a stacked films thereof. Here, an example of using aluminum oxide for the protective film 125Rf1 and tungsten for the protective film 125Rf2 is described. A protective film formed by stacking different types of films can have high resistance to the manufacturing environment. Furthermore, the protective film 125Rf1 may have a stacked structure including an aluminum oxide film formed by an ALD method and a silicon nitride film formed by a sputtering method.

When the protective films 125Rf1 and film 125Rf2 are formed by an ALD method and a sputtering method, the suitable film-formation temperature is set to be higher than or equal to room temperature and lower than or equal to 140° C., preferably higher than or equal to room temperature and lower than or equal to 120° C., further preferably higher than or equal to room temperature and lower than or equal to 100° C., in which case the impact on the EL layer can be reduced. In the case where each of the protective layer 125R1 and the protective layer 125R2 has a stacked-layer structure, it is preferable to reduce the stress of the stacked-layer structure. Specifically, a stress applied to each layer in the stacked structure is preferably higher than or equal to −500 MPa and less than or equal to +500 MPa, further preferably higher than or equal to −200 MPa and lower than or equal to +200 MPa, in which case troubles in the process, such as film separation and peeling, can be suppressed.

<Formation of Resist Mask 143a>

Next, a resist mask 143a is formed over the pixel electrode 111 in a portion corresponding to the light-emitting device 110R (see FIG. 17C). The resist mask 143a can be formed by a lithography step.

### <Formation of Protective Layers 125R1 and 125R2>

Next, the protective film 125Rf1 and the protective film 125Rf2 are etched using the resist mask 143a as a mask, so that the protective layer 125R1 and the protective layer 125R2 each of which has an island shape are formed. In this etching, a dry etching method or a wet etching method can be used. After that, the resist mask 143a is removed by ashing or using a resist stripper (see FIG. 17D).

### <Formation of EL Layer 112R>

Next, the EL film 112Rf is etched using the protective layers 125R1 and 125R2 as a mask, so that the EL layer 112R with an island shape is formed. In this etching, a dry etching method is preferably used.

### <Formation of EL Film 112Gf>

Next, a baking step for removing moisture remaining on the surface of the pixel electrode 111 is performed. A vacuum baking apparatus or a film-formation apparatus can be used for the baking step. As the condition which does not give damage to the EL layer 112R, the vacuum baking is performed at a temperature lower than or equal to 100° C., preferably, lower than or equal to 90° C., further preferably lower than or equal to 80° C. In the case of vacuum baking at 80° C., the sufficient amount of moisture (H₂O) has been released in 30 minutes or more according to the measurement by thermal desorption spectroscopy (TDS).

Next, surface treatment of the exposed pixel electrode 111 is performed. For example, the surface of the pixel electrode 111 is irradiated with plasma generated using a fluorine-based gas such as CF₄ with a plasma treatment apparatus. Then, an EL film 112Gf is formed over the pixel electrode 111. The EL film 112Gf is processed, whereby the EL layer 112G that is a component of the light-emitting device 110G can be formed.

The EL film 112Gf at least includes an organic compound film emitting green light. A structure may be employed in which at least one of films functioning as an electron-injection layer, an electron-transport layer, a charge-generation layer, a hole-transport layer, and a hole-injection layer is stacked in addition to the above.

### <Formation of Protective Films 125Gf1 and 125Gf2>

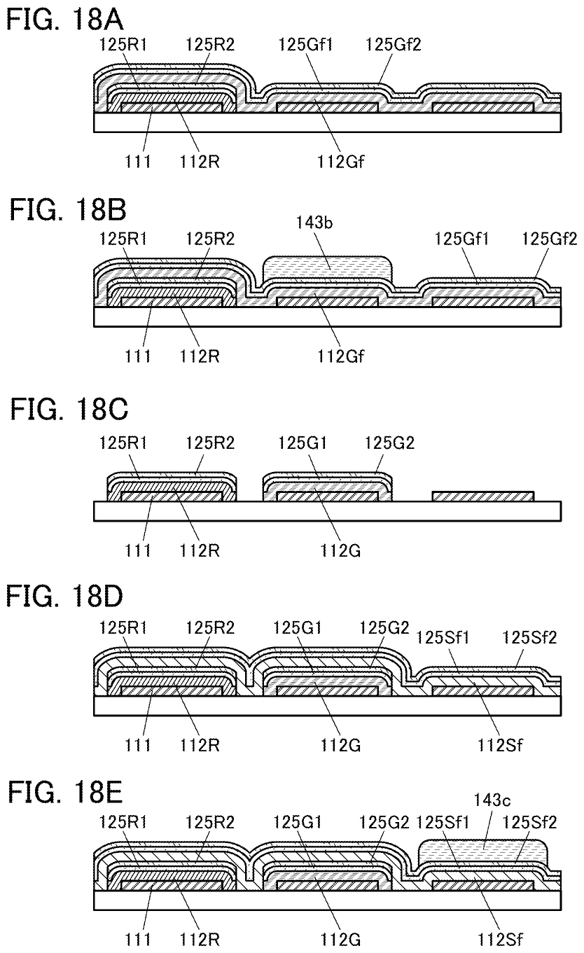

Next, a protective film 125Gf1 and a protective film 125Gf2 that are to be a protective layer 125G1 and a protective layer 125G2 are formed over the EL film 112Gf (see FIG. 18A). The protective film 125Gf1 can be formed using a material same as that of the protective film 125Rf1. The protective film 125Gf2 can be formed using a material same as that of the protective film 125Rf2.

<Formation of Resist Mask 143b>

Next, a resist mask 143b is formed over the pixel electrode 111 in a portion corresponding to the light-emitting device 110G (see FIG. 18B). The resist mask 143b can be formed by a lithography step.

### <Formation of Protective Layers 125G1 and 125G2>

Then, the protective film 125Gf1 and the protective film 125Gf2 are etched using the resist mask 143b as a mask, so that the protective layer 125G1 and the protective layer 125G2 each of which has an island shape are formed. In this etching step, a dry etching method or a wet etching method can be used. After that, the resist mask 143b is removed by ashing or using a resist stripper.

### <Formation of EL Layer 112G>

Next, the EL film 112Gf is etched using the protective layers 125G1 and 125G2 as a mask, so that the EL layer 112G with an island shape is formed (see FIG. 18C). In this etching step, a dry etching method is preferably used.

### <Formation of Components in Light-Emitting Device 110B>

The next step is for formation of an EL layers and the like included in the light-emitting device 110B; however, description thereof is omitted.

### <Formation of Organic Film 112Sf>

Next, a baking step for removing moisture remaining on the surface of the pixel electrode 111 is performed. A vacuum baking apparatus or a film-formation apparatus can be used for the baking step. As the condition which does not give damage to the EL layers 112R and 112G, the vacuum baking is performed at a temperature lower than or equal to 100° C., preferably, lower than or equal to 90° C., further preferably lower than or equal to 80° C.

Next, surface treatment is performed on the exposed pixel electrode 111. For example, the surface of the pixel electrode 111 is irradiated with plasma generated using a fluorine-based gas such as CF₄ with a plasma treatment apparatus. Then, an organic film 112Sf that is to be the organic layer 112S is formed over the pixel electrode 111.

The organic film 112Sf includes an organic compound film having a photoelectric conversion property. A structure may be employed in which at least one of films functioning as an electron-injection layer, an electron-transport layer, a charge-generation layer, a hole-transport layer, and a hole-injection layer is stacked in addition to the above.

### <Formation of Protective Films 125Sf1 and 125Sf2>

Next, a protective film 125Sf1 and a protective film 125Sf2 that are to be a protective layer 125S1 and a protective layer 125S2 are formed over the organic film 112Sf (see FIG. 18D). The protective film 125Sf1 can be formed using a material same as that of the protective film 125Rf1. The protective film 125Sf2 can be formed using a material same as that of the protective film 125Rf2.

<Formation of Resist Mask 143c>

Next, a resist mask 143c is formed over the pixel electrode 111 in a portion corresponding to the light-receiving device 110S (see FIG. 18E). The resist mask 143c can be formed by a lithography step.

### <Formation of Protective Layers 125S1 and 125S2>

Next, the protective film 125Sf1 and the protective film 125Sf2 are etched using the resist mask 143c as a mask, so that the protective layer 125S1 and the protective layer 125S2 each of which has an island shape are formed. In this etching step, a dry etching method or a wet etching method can be used. After that, the resist mask 143c is removed by ashing or using a resist stripper.

### <Formation of Organic Layer 112S>

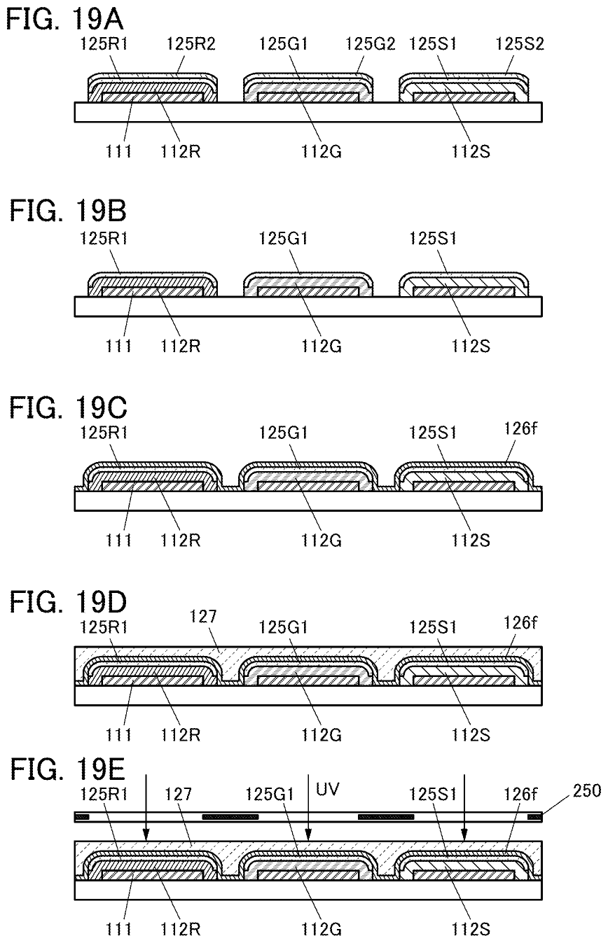

Next, the organic film 112Sf is etched using the protective layers 125S1 and 125S2 as a mask, so that the organic layer 112S with an island shape is formed (see FIG. 19A). In this etching step, a dry etching method is preferably used.

### <Removal of Protective Layers 125R2, 125G2, and 125S2>

Next, the protective layer 125R2, the protective layer 125G2, and the protective layer 125S2 are removed (see FIG. 19B). A dry etching method or a wet etching method is preferably used for the removal of the protective layers 125R2, 125G2, and 125S2. In addition, the side surfaces of the EL layer 112R, the EL layer 112G, and the organic layer 112S and the like may be cleaned with a plasma treatment apparatus or the like.

<Formation of Barrier Film 126f>

Next, a barrier film 126f that is to be a barrier layer 126 is formed to cover the protective layer 125R1, the protective layer 125G1, the protective layer 125S1, and the side surfaces of the EL layer 112R, the EL layer 112G, and the organic layer 112S (see FIG. 19C). With the barrier layer 126, the side surfaces of the EL layer 112R, the EL layer 112G, and the organic layer 112S can be sealed, whereby the reliability of the light-emitting device and the light-receiving device can be improved. As the barrier film 126f, an inorganic film same as the protective film 125Rf1 can be formed by a CVD method, an ALD method, a sputtering method, or the like.

### <Formation of Insulating Layer 127>

Next, an insulating layer 127 is formed so that spaces between the pixel electrodes, between the EL layers, and between the EL layer and the organic layer are filled therewith. The formation of the insulating layer 127 can eliminate steps, which can prevent disconnection of a conductive film (common electrode) formed over the EL layers and the organic layer in a later step. Furthermore, the insulating layer 127 covers the vicinity of the side surfaces of the EL layers and the organic layer, which can prevent entry of impurities against the EL layers and the organic layer, peeling of the layers, and the like. Note that the insulating layer 127 can be referred to as an interlayer insulating layer provided between the conductive film and the pixel electrode 111.

As the insulating layer 127, an organic insulating layer is preferably used. Examples of materials used for the insulating layer 127 include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. Examples of organic materials used for the insulating layer 127 include polyvinyl alcohol (PVA), polyvinyl butyral, polyvinyl pyrrolidone, polyethylene glycol, polyglycerin, pullulan, water-soluble cellulose, and an alcohol-soluble polyamide resin. Moreover, the insulating layer 127 can be formed using a photosensitive resin. The photosensitive resin may be formed using either of a positive-type material or a negative-type material and can be formed with a step similar to the lithography step, for example.

Here, an example of using a positive photosensitive resin for the insulating layer 127 is described. First, the insulating layer 127 is formed over the barrier film 126f with an apparatus for coating of the above resin (see FIG. 19D), and pre-baking is performed with a baking apparatus.

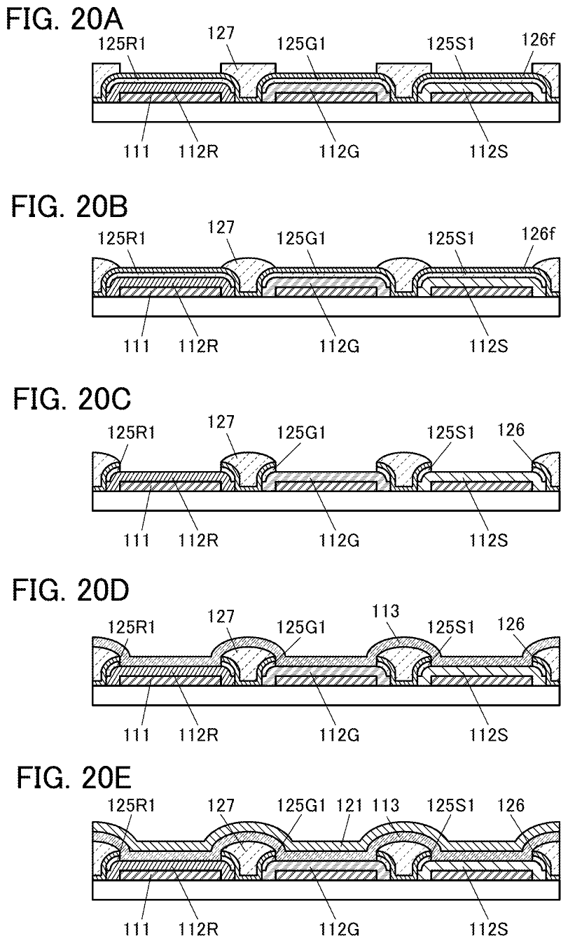

Next, a region where the insulating layer 127 is not needed is irradiated with ultraviolet light UV through a photomask 250 (see FIG. 19E). Then, the region is removed by a development step (see FIG. 20A).

Next, post-baking is performed with the baking apparatus. Note that depending on a material to be used, irradiation with ultraviolet light is performed before the post-baking, in some cases, to promote the curing reaction of a resin.

By the post-baking, the insulating layer 127 is reflowed to have a curved top surface (see FIG. 20B). When the top surface of the insulating layer 127 is curved, the coverage of the conductive film (common electrode) formed in the later step can be improved and the disconnection can be prevented. Note that in some cases, the insulating layer 127 at the time of undergoing the development step may have a curved top surface.

### <Formation of Barrier Layer 126>

Next, the barrier film 126f and the protective layers 125R1, 125G1, and 125S1 are removed by a dry etching method using the insulating layer 127 as a mask, so that the barrier layer 126 is formed (see FIG. 20C). By this step, the top surfaces of the EL layer 112R, the EL layer 112G, and the organic layer 112S are exposed.

Note that by this step, the protective layers 125R1, 125G1, and 125S1 are partly left between the barrier layer 126 and the EL layer 112R, between the barrier layer 126 and the EL layer 112G, and between the barrier layer 126 and the organic layer 112S. Therefore, diffusion of impurities from the insulating layer 127 to the EL layer 112R, the EL layer 112G, and the organic layer 112S can be greatly inhibited.

Although the example described here is that the barrier film 126f and the protective layers 125R1, 125G1, and 125S1 are removed in one step, a removal of the barrier film 126f and a removal of the protective layers 125R1, 125G1, and 125S1 may be performed in different steps. For example, one of the removal steps may be performed by a dry etching method, and the other may be performed by a wet etching method. Alternatively, after one of the removal steps is performed, the end portion of the insulating layer 127 may be made to recede, and then the other removal step may be performed. This method enables a hollow to be less likely to be generated below the insulating layer 127.

### <Formation of Common Electrode>

Next, a conductive film that is to be the common electrode 113 of the light-emitting device and the light-receiving device is formed over the insulating layer 127, and the EL layer 112R, the EL layer 112G, and the organic layer 112S which are exposed in the previous step (see FIG. 20D). As the common electrode 113, a single film formed using any one of a thin metal film that transmits light emitted from the light-emitting layer (e.g., an alloy film of silver and magnesium, or the like) and a light-transmitting conductive film (e.g., an indium tin oxide film or an oxide film containing at least one of indium, gallium, zinc, and the like) or a stacked film thereof can be used. The common electrode 113 formed using such a film can be referred to as an electrode having a light-transmitting property. For the step of forming the conductive film to be the common electrode 113, an evaporation apparatus and/or a sputtering apparatus can be used.

Note that before the formation of the common electrode 113, a layer having a function of any of an electron-injection layer, an electron-transport layer, a charge-generation layer, a hole-transport layer, and a hole-injection layer may be provided as a common layer over the EL layer 112R, the EL layer 112G, and the organic layer 112S, so that the reliability is improved.

The light-reflective electrode is provided as the pixel electrode 111, and the light-transmitting electrode is provided as the common electrode 113, so that light emitted from the light-emitting layer can be ejected to the outside through the common electrode 113. In other words, a top-emission light-emitting device is formed. Furthermore, a light-receiving device in which a light is received on the common electrode 113 side is formed.

### <Formation of Protective Layer>

Next, the protective layer 121 is formed over the common electrode 113 (see FIG. 20E). A sputtering apparatus, a CVD apparatus, an ALD apparatus, or the like can be used for the step of forming the protective layer 121.

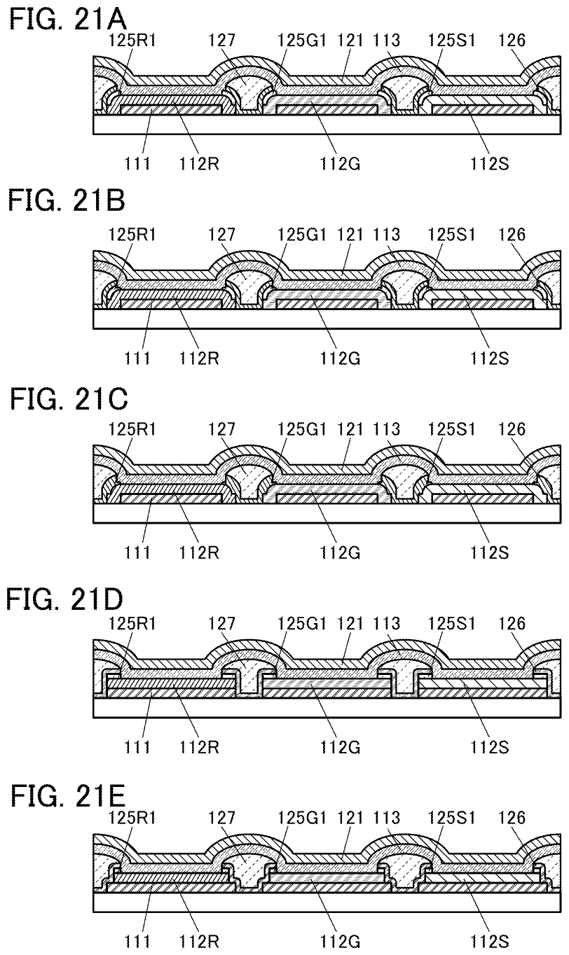

The above is an example of a manufacturing method of a light-emitting device and a light-receiving device which can be manufactured using manufacturing equipment of one embodiment of the present invention. In the case where the protective layers 125R1, 125G1, and 125S1 are removed after making the end portion of the insulating layer 127 recede by the ashing step after the removal of the barrier film 126f as described with FIG. 20C, a structure illustrated in FIG. 21A is obtained. Note that as illustrated in FIG. 21B, steps may be generated at end portions of the protective layers 125R1, 125G1, and 125S1.

Shapes in cross section of layers in the light-emitting device and the light-receiving device can be observed with a scanning electron microscope (SEM), a transmission electron microscope (TEM), or the like. In the case where the barrier layer 126 and the protective layers 125R1, 125G1, and 125S1 are formed using the same material, the interfaces of the layers are not clearly observed, and a shape illustrated in FIG. 21C is observed in some cases.

In the light-emitting device and the light-receiving device which can be manufactured with manufacturing equipment of one embodiment of the present invention, the pixel electrode 111, the EL layers, and the organic layers may have areas equal to each other as illustrated in FIG. 21D. Alternatively, as illustrated in FIG. 21E, the EL layers and the organic layer may have a smaller area than the pixel electrode 111.

### <Example of Manufacturing Equipment>

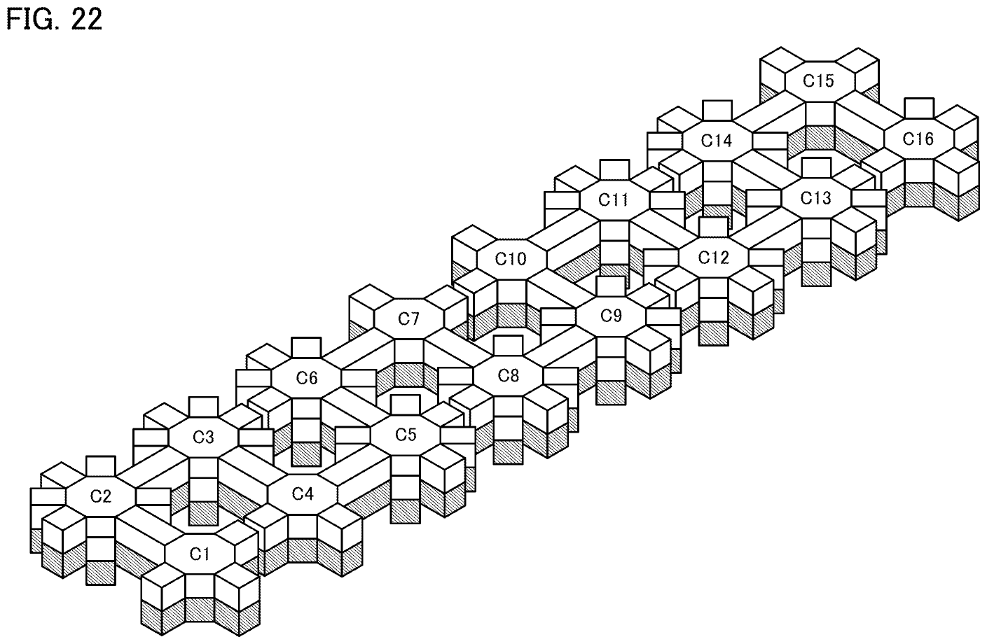

FIG. 22 illustrates an example of manufacturing equipment that can be used for formation steps from the EL film 112Rf up to the protective layer 121. The basic structure of the manufacturing equipment illustrated in FIG. 22 is the same as that in the block diagram of FIG. 5.

The cluster C1 to the cluster C16 are specifically described below. FIG. 22 is a schematic perspective view of the whole of the manufacturing equipment, where utilities, gate valves, and the like are not illustrated.

### <Cluster C1>

In the cluster C1, a cleaning step before formation of the EL film 112Rf is performed. The cluster C1 includes a cleaning apparatus and a baking apparatus.

### <Cluster C2>

The clusters C2 to C4 are each a group of apparatuses for forming a component of the light-emitting device 110R. In the cluster C2, a step of forming the EL film 112Rf is performed. The cluster C2 includes a surface treatment apparatus with which surface treatment is performed on a base of the EL film 112Rf (pixel electrode 111), an evaporation apparatus with which the EL film 112Rf (at least one of organic compound layers such as a light-emitting layer (red), an electron-injection layer, an electron-transport layer, a charge-generation layer, a hole-transport layer, and a hole-injection layer) is formed, and a film-formation apparatus (e.g., a sputtering apparatus, an ALD apparatus, or the like) with which the protective films 125Rf1 and 125Rf2 are formed.

### <Cluster C3>

In the cluster C3, a lithography step for forming the resist mask 143a is performed. The cluster C3 includes a resist (photoresist) coating apparatus, a pre-baking apparatus, a light-exposure apparatus, a development apparatus, and a post-baking apparatus. Alternatively, a nanoimprint apparatus can be included.

### <Cluster C4>

In the cluster C4, etching of the protective films 125Rf1 and 125Rf2 and the EL film 112Rf and removal of the resist mask 143a are performed. The cluster C4 includes a first dry etching apparatus with which the protective films 125Rf1 and 125Rf2 are etched and a second dry etching apparatus with which formation of the EL layer 112R and ashing of the resist mask 143a are performed.

### <Cluster C5>

The clusters C5 to C7 are each a group of apparatuses for forming a component of the light-emitting device 110G. In the cluster C5, a step of forming the EL film 112Gf is performed. The cluster C5 includes a surface treatment apparatus with which surface treatment is performed on a base of the EL film 112Gf (pixel electrode 111), an evaporation apparatus with which the EL film 112Gf (at least one of organic compound layers such as a light-emitting layer (green), an electron-injection layer, an electron-transport layer, a charge-generation layer, a hole-transport layer, and a hole-injection layer) is formed, and a film-formation apparatus (e.g., a sputtering apparatus, an ALD apparatus, or the like) with which the protective films 125Gf1 and 125Gf2 are formed.

### <Cluster C6>

In the cluster C6, a lithography step for forming the resist mask 143b is performed. The cluster C6 includes a resin (photoresist) coating apparatus, a pre-baking apparatus, a light-exposure apparatus, a development apparatus, and a post-baking apparatus. Alternatively, a nanoimprint apparatus can be included.

### <Cluster C7>

In the cluster C7, etching of the protective films 125Gf1 and 125Gf2 and the EL film 112Gf and removal of the resist mask 143b are performed. The cluster C7 includes a first dry etching apparatus with which the protective films 125Gf1 and 125Gf2 are etched and a second dry etching apparatus with which formation of the EL layer 112G and ashing of the resist mask 143b are performed.

### <Clusters C8 to C10>

The clusters C8 to C10 are each a group of apparatuses for forming a component of the light-emitting device 110B (including a light-emitting layer (blue)). Apparatuses included in the cluster C8 are similar to those in the clusters C2 and C5. Apparatuses included in the cluster C9 are similar to those in the clusters C3 and C6. Apparatuses included in the cluster C10 are similar to those in the clusters C4 and C7.

### <Cluster C11>

The clusters C11 to C13 are each a group of apparatuses for forming a component of the light-receiving device 110S. In the cluster C11, a step of forming the organic film 112Sf is performed. The cluster C11 includes a surface treatment apparatus with which surface treatment is performed on a base of the organic film 112Sf (pixel electrode 111), an evaporation apparatus with which the organic film 112Sf (at least one of organic compound layers such as a photoelectric conversion layer, an electron-injection layer, an electron-transport layer, a charge-generation layer, a hole-transport layer, and a hole-injection layer) is formed, and a film-formation apparatus (e.g., a sputtering apparatus, an ALD apparatus, or the like) with which the protective films 125Sf1 and 125Sf2 are formed.

### <Cluster C12>

In the cluster C12, a lithography step for forming the resist mask 143c is performed. The cluster C12 includes a resin (photoresist) coating apparatus, a pre-baking apparatus, a light-exposure apparatus, a development apparatus, and a post-baking apparatus. Alternatively, a nanoimprint apparatus can be included.

### <Cluster C13>

In the cluster C13, etching of the protective films 125Sf1 and 125Sf2 and the organic film 112Sf, removal of the resist mask 143c and the protective films 125Rf2, 125Gf2 and 125Sf2, surface cleaning, and formation of the barrier layer 126 are performed.

The cluster C13 includes a first dry etching apparatus with which the protective films 125Sf1 and 125Sf2 are etched, a second dry etching apparatus with which formation of the organic layer 112S and ashing of the resist mask 143c are performed, a third dry etching apparatus with which the protective films 125Rf2, 125Gf2, and 125Sf2 are removed, a plasma treatment apparatus with which side surfaces of the EL layer 112R, the EL layer 112G, and the organic layer 112S are cleaned, and a film-formation apparatus (e.g., a sputtering apparatus, an ALD apparatus, or the like) with which the barrier film 126f is formed.

### <Cluster C14>

In the cluster C14, formation of the insulating layer 127 is performed. The cluster C14 can includes an apparatus that can be used for a lithography step, for example, a resin coating apparatus, a pre-baking apparatus, a first light-exposure apparatus, a development apparatus, and a post-baking apparatus. In addition, a second light-exposure apparatus may be included.

### <Cluster C15>

In the cluster C15, etching of the barrier film 126f and the protective films 125Rf1, 125Gf1, and 125Sf1 is performed. The cluster C15 includes a wet etching apparatus with which the barrier film 126f and the protective films 125Rf1, 125Gf1, and 125Sf1 are etched.

### <Cluster C16>

In the cluster C16, formation of the organic compound layer, the common electrode 113, and the protective layer 121 is performed. The cluster C16 includes an evaporation apparatus with which at least one of organic compound layers such as an electron-injection layer, an electron-transport layer, a charge-generation layer, a hole-transport layer, and a hole-injection layer is formed, a film-formation apparatus (e.g., a sputtering apparatus, an ALD apparatus, or the like) with which the common electrode 113 is formed, and a film-formation apparatus (e.g., a sputtering apparatus, an ALD apparatus, or the like) with which the protective layer 121 is formed.

Table 1 and Table 2 each a summary of steps and processing apparatuses in the manufacturing equipment illustrated in FIG. 22 and corresponding components formed in the manufacturing method illustrated in FIG. 17A to FIG. 20E. Note that components of the light-emitting device B are not shown in the tables. The steps shown in Table 1 and Table 2 are just examples, and other steps can be performed with the manufacturing equipment.

TABLE 1

| Step | | Processing | Corresponding |
|---|---|---|---|
| No. | Step | cluster | component |
| 1 | Cleaning | C1 | |
| 2 | Baking | | |
| 3 | Surface treatment of pixel electrode | C2 | 111 |
| 4 | Formation of organic compound layer | | 112Rf |
| 5 | Formation of organic compound layer (light-emitting layer (R)) | | |
| 6 | Formation of organic compound layer | | |
| 7 | Formation of protective film (1st + 2nd inorganic films) | | 125Rf1, 125Rf2 |
| 8 | Photoresist coating | C3 | 143a |
| 9 | Pre-baking | | |
| 10 | Light exposure | | |
| 11 | Development | | |
| 12 | Post-baking | | |
| 13 | Etching of protective film (1st + 2nd inorganic films) | C4 | 125R1, 125R2 |
| 14 | Etching of organic compound layer (removal of photoresist) | | 112R |
| 15 | Surface treatment of pixel electrode | C5 | 111 |
| 16 | Formation of organic compound layer | | 112Gf |
| 17 | Formation of organic compound layer (light-emitting layer (G)) | | |
| 18 | Formation of organic compound layer | | |
| 19 | Formation of protective film (1st + 2nd inorganic films) | | 125Gf1, 125Gf2 |
| 20 | Photoresist coating | C6 | 143b |
| 21 | Pre-baking | | |
| 22 | Light exposure | | |
| 23 | Development | | |
| 24 | Post-baking | | |
| 25 | Etching of protective film (1st + 2nd inorganic films) | C7 | 125G1, 125G2 |
| 26 | Etching of organic compound layer | | 112G |
| 27 | Surface treatment of pixel electrode | C8 | — |
| 28 | Formation of organic compound layer | | — |
| 29 | Formation of organic compound layer (light-emitting layer (B)) | | |
| 30 | Formation of organic compound layer | | |
| 31 | Formation of protective film (1st + 2nd inorganic films) | | — |
| 32 | Photoresist coating | C9 | — |
| 33 | Pre-baking | | |
| 34 | Light exposure | | |
| 35 | Development | | |
| 36 | Post-baking | | |
| 37 | Etching of protective film (1st + 2nd inorganic films) | C10 | — |
| 38 | Etching of organic compound layer | | — |

TABLE 2

| Step | | Processing | Corresponding |
|---|---|---|---|
| No. | Step | cluster | component |
| 39 | Surface treatment of pixel electrode | C11 | 111 |
| 40 | Formation of organic compound layer | | 112Sf |
| 41 | Formation of organic compound layer (photoelectric conversion layer) | | |
| 42 | Formation of organic compound layer | | |
| 43 | Formation of protective film (1st + 2nd inorganic films) | | 125Sf1, 125Sf2 |
| 44 | Photoresist coating | C12 | 143c |
| 45 | Pre-baking | | |
| 46 | Light-exposure | | |
| 47 | Development | | |
| 48 | Post-baking | | |
| 49 | Etching of protective film (1st + 2nd inorganic films) | C13 | 125S1, 125S2 |
| 50 | Etching of organic compound layer | | 112S |
| 51 | Etching of protective film (2nd inorganic film) | | 125R2, 125G2, 125S2 |
| 52 | Surface cleaning | | 112R, 112G, 112S |
| 53 | Standby | | |
| 54 | Formation of barrier film (3rd inorganic film) | | 126f |
| 55 | Photosensitive resin coating | C14 | 127 |
| 56 | Pre-baking | | |
| 57 | Light-exposure 1 | | |
| 58 | Development | | |
| 59 | Light-exposure 2 | | |
| 60 | Post-baking (reflow) | | |
| 61 | Etching of protective layer (3rd inorganic film) | C15 | 126 |
| 62 | Etching of protective layer (1st inorganic film) | | 125R1, 125G1, 125S1 |
| 63 | Formation of organic compound layer | C16 | 113 |
| 64 | Formation of common electrode | | |
| 65 | Formation of protective layer | | 121 |

The manufacturing equipment of one embodiment of the present invention has a function of executing steps Nos. 1 to 53 shown in Table 1 automatically.

This embodiment can be implemented in an appropriate combination with any of the structures described in the other embodiments.

This application is based on Japanese Patent Application Serial No. 2021-124384 filed with Japan Patent Office on Jul. 29, 2021 and Japanese Patent Application Serial No. 2021-129145 filed with Japan Patent Office on Aug. 5, 2021, the entire contents of which are hereby incorporated by reference.

What is claimed is:

1. An equipment for manufacturing a light-emitting device and a light-receiving device comprising:
a first cluster;
a second cluster;
a third cluster;
a fourth cluster;
a fifth cluster;
a sixth cluster; and
a seventh cluster,
wherein the second cluster is connected to the first cluster through a first buffer chamber,
wherein the third cluster is connected to the second cluster through a second buffer chamber,
wherein the fourth cluster is connected to the third cluster through a third buffer chamber,
wherein the fifth cluster is connected to the fourth cluster through a fourth buffer layer,
wherein the sixth cluster is connected to the fifth cluster through a fifth buffer chamber,
wherein the seventh cluster is connected to the sixth cluster through a sixth buffer chamber,
wherein the first cluster is configured to form a first stacked film in which a first organic compound film, a first inorganic film, and a second inorganic film are stacked in this order,
wherein the second cluster is configured to form a first resist mask over the first stacked film,
wherein the third cluster is configured to form a light-emitting layer of the light-emitting device by etching the first stacked film and to remove the first resist mask,
wherein the fourth cluster is configured to form a second stacked film in which a second organic compound film, a third inorganic film, and a fourth inorganic film are stacked in this order,
wherein the fifth cluster is configured to form a second resist mask over the second stacked film,
wherein the sixth cluster is configured to form a photoelectric conversion layer of the light-receiving device by etching the second stacked film, to remove the second resist mask, to remove the second inorganic film and the fourth inorganic film, and to form a fifth inorganic film covering a side surface of the light-emitting layer and a side surface of the photoelectric conversion layer, and
wherein the seventh cluster is configured to coat the fifth inorganic film with a resin in an inert gas atmosphere, to remove a part of the resin, and to cure the resin.

2. The equipment for manufacturing a light-emitting device and a light-receiving device according to claim 1,
wherein the sixth cluster comprises a first dry etching apparatus, a second dry etching apparatus, a third dry etching apparatus, and a film-formation apparatus, and
wherein the seventh cluster comprises a coating apparatus, a first baking apparatus, a light-exposure apparatus, a development apparatus, and a second baking apparatus.

3. The equipment for manufacturing a light-emitting device and a light-receiving device according to claim 2,
wherein the second dry etching apparatus is configured to perform ashing.

4. The equipment for manufacturing a light-emitting device and a light-receiving device according to claim 2,
wherein the film-formation apparatus is an ALD apparatus.

5. The equipment for manufacturing a light-emitting device and a light-receiving device according to claim 1, further comprising:
an eighth cluster,
wherein the eighth cluster is connected to the seventh cluster though a seventh buffer chamber, and
wherein the eighth cluster is configured to etch the fifth inorganic film, the first inorganic film, and the third inorganic film with use of the resin as a mask.

6. The equipment for manufacturing a light-emitting device and a light-receiving device according to 5,
wherein the eighth cluster comprises a fourth dry etching apparatus and a first wet etching apparatus.

7. The equipment for manufacturing a light-emitting device and a light-receiving device according to 5,
wherein the eighth cluster comprises a first wet etching apparatus and a second wet etching apparatus.

8. The equipment for manufacturing a light-emitting device and a light-receiving device according to 1, further comprising:
an eighth cluster,
wherein the eight cluster is connected to the seventh cluster through a seventh buffer chamber, and
wherein the eighth cluster is configured to etch the fifth inorganic film with use of the resin as a mask, make an end portion of the resin recede by ashing, and to etch the first inorganic film and the third inorganic film.

9. The equipment for manufacturing a light-emitting device and a light-receiving device according to 8,
wherein the eighth cluster comprises a fourth dry etching apparatus, a dry etching apparatus configured to perform ashing or an ashing apparatus, and a first wet etching apparatus.

10. The equipment for manufacturing a light-emitting device and a light-receiving device according to 8,
wherein the eighth cluster comprises a first wet etching apparatus, a dry etching apparatus configured to perform ashing or an ashing apparatus, and a second wet etching apparatus.

11. The equipment for manufacturing a light-emitting device and a light-receiving device according to claim 5, further comprising:
a ninth cluster,
wherein the ninth cluster is connected to the eighth cluster through an eighth buffer chamber, and
wherein the ninth cluster is configured to form a conductive layer and an insulating layer over the light-emitting layer and the photoelectric conversion layer.

12. The equipment for manufacturing a light-emitting device and a light-receiving device according to claim 11,
wherein the ninth cluster comprises at least two of an evaporation apparatus, a sputtering apparatus, and an ALD apparatus.
